(19) United States
(12) Patent Application Publication
(10) Pub. No.: US 2025/0048638 A1
(43) Pub. Date: Feb. 6, 2025

(54) SEMICONDUCTOR DEVICE AND ELECTRONIC SYSTEM INCLUDING THE SAME

(71) Applicant: SAMSUNG ELECTRONICS CO., LTD., Suwon-Si (KR)

(72) Inventors: HAKSEON KIM, Suwon-si (KR); KANG-OH YUN, Suwon-si (KR); DONGJIN LEE, Suwon-si (KR); YOUNGROK KIM, Suwon-si (KR); RYOONGBIN LEE, Suwon-si (KR); JAEDUK LEE, Suwon-si (KR)

(21) Appl. No.: 18/432,459

(22) Filed: Feb. 5, 2024

(30) Foreign Application Priority Data
Aug. 1, 2023 (KR) 10-2023-0100636

(51) Int. Cl. H10B 43/40; G11C 16/24; H10B 43/27

(52) U.S. Cl. CPC H10B 43/40; H10B 43/27; G11C 16/24

(57) ABSTRACT

Disclosed are a semiconductor device and an electronic system including the semiconductor device. The semiconductor device includes a semiconductor substrate including a plurality of trenches and silicon, a gate electrode positioned on the semiconductor substrate and between the trenches, and a source region and a drain region respectively positioned within the trenches. The source region and the drain region include silicon carbide (SiC) or gallium nitride (GaN), the source region and the drain region each includes a first lightly doped region and a second lightly doped region, and a whole of the first lightly doped region overlaps the second lightly doped region in a direction perpendicular to an upper surface of the semiconductor substrate.

### CROSS-REFERENCE TO RELATED APPLICATION

This application claims priority under 35 U.S.C. § 119 to Korean Patent Application No. 10-2023-0100636, filed on Aug. 1, 2023, in the Korean Intellectual Property Office, the entire contents of which are incorporated by reference herein.

### TECHNICAL FIELD

The present disclosure relates to a semiconductor device and an electronic system including the same.

### DISCUSSION OF RELATED ART

A semiconductor is a material with an electrical conductivity value that falls between that of a conductor and that of an insulator, and refers to a material that conducts electricity under predetermined conditions. Different semiconductors may have different bandgaps. The size of the bandgap can affect the properties of the material and how it behaves in a transistor. Various semiconductor devices such as, for example, memory devices, can be manufactured using these semiconductor materials. The semiconductor materials having bandgaps of specific sizes may be selected for manufacturing based on what the semiconductor devices to be applied for. Memory devices may be classified into volatile memory devices and non-volatile memory devices. In the case of non-volatile memory devices, contents may not be deleted even if power is cut off, and may be used in various electronic devices such as portable phones, digital cameras, and PCs.

In accordance with the recent trend of increasing storage capacity, the degree of integration of the non-volatile memory devices is required to be increased. The degree of integration of the non-volatile memory devices arranged in two dimensions on a plane may be limited. Accordingly, a vertical non-volatile memory device arranged in three dimensions has been proposed.

### SUMMARY

The present disclosure provides a semiconductor device capable of high-voltage driving and an electronic system including the same.

A semiconductor device according to an embodiment of the present disclosure includes a semiconductor substrate including a plurality of trenches and silicon, a gate electrode positioned on the semiconductor substrate and between the trenches, and a source region and a drain region respectively positioned within the trenches. The source region and the drain region include SiC or GaN, the source region and the drain region each includes a first lightly doped region and a second lightly doped region, and a whole of the first lightly doped region overlaps the second lightly doped region in a direction perpendicular to an upper surface of the semiconductor substrate.

A semiconductor device according to an embodiment of the present disclosure includes a periphery circuit structure, and a cell array structure disposed on the peripheral circuit structure, the cell array structure includes memory cells arranged three-dimensionally on a semiconductor layer, the peripheral circuit structure includes a semiconductor substrate including a plurality of trenches and silicon, a gate electrode positioned on the semiconductor substrate and between the trenches, and a source region and a drain region respectively positioned within the trenches. The source region and the drain region include SiC or GaN, the source region and the drain region each includes a first lightly doped region and a second lightly doped region, and a whole of the first lightly doped region overlaps the second lightly doped region in a direction perpendicular to an upper surface of the semiconductor substrate.

An electronic system according to an embodiment of the present disclosure includes a main substrate, a semiconductor device disposed on the main substrate, and a controller electrically connected to the semiconductor device on the main substrate, the semiconductor device includes a periphery circuit structure, and a cell array structure positioned above the peripheral circuit structure, the cell array structure includes memory cells arranged three-dimensionally on a semiconductor layer, the peripheral circuit structure includes a semiconductor substrate including a plurality of trenches and silicon, a gate electrode positioned on the semiconductor substrate and between the trenches, and a source region and a drain region respectively positioned within the trenches. The source region and the drain region include SiC or GaN, the source region and the drain region each includes a first lightly doped region and a second lightly doped region, and a whole of the first lightly doped region overlaps the second lightly doped region in a direction perpendicular to an upper surface of the semiconductor substrate.

### BRIEF DESCRIPTION OF THE DRAWINGS

Embodiments of the present disclosure will be more clearly understood from the following detailed description taken in conjunction with the accompanying drawings in which:

FIG. 1 is a top plan view illustrating a part of a semiconductor device according to an embodiment of the present disclosure;

FIG. 2 is a cross-sectional view of a part of a semiconductor device according to an embodiment of the present disclosure, taken along line I-I′ of FIG. 1;

FIG. 3 is a diagram illustrating the same region as FIG. 2 for an embodiment of the present disclosure;

FIG. 4 is a diagram illustrating the same region as FIG. 1 for an embodiment of the present disclosure;

FIG. 5 is a cross-sectional view taken along line V-V′ of FIG. 4;

FIG. 6 is a diagram illustrating the same region as FIG. 4 for an embodiment of the present disclosure;

FIGS. 7 to 16 are diagrams illustrating the same region as FIG. 2 for an embodiment of the present disclosure;

FIGS. 17 to 31 are cross-sectional views illustrating a method of manufacturing a semiconductor device according to an embodiment of the present disclosure;

FIGS. 32 to 35 are cross-sectional views illustrating a semiconductor device according to an embodiment of the present disclosure;

FIG. 36 is a diagram schematically illustrating an electronic system including a semiconductor device according to an embodiment of the present disclosure;

FIG. 37 is a perspective view schematically illustrating an electronic system including a semiconductor device according to an embodiment of the present disclosure; and

FIGS. 38 and 39 are cross-sectional views, schematically illustrating a semiconductor package according to an embodiment of the present disclosure, respectively.

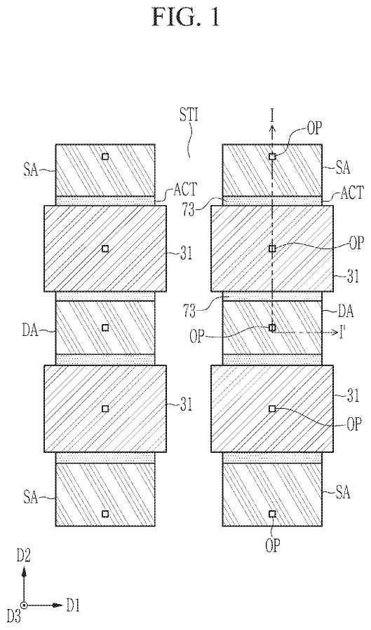

Since the drawings in FIGS. 1-39 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

It will be understood that when an element such as a layer, a film, a region, or a substrate is referred to as being “on” or “above” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity. It will be understood that the spatially relative terms are intended to encompass different orientations of the device in use or in operation, in addition to the orientation depicted in the figures.

Unless explicitly described to the contrary, the word “comprise”, and variations such as “comprises” or “comprising”, will be understood to imply the inclusion of stated elements but not the exclusion of any other elements.

Throughout the specification, the phrase “in a plan view” or “on a plane” means viewing a target portion from the top, and the phrase “in a cross-sectional view” or “on a cross-section” means viewing a cross-section, which is formed by vertically cutting a target portion, from the side.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

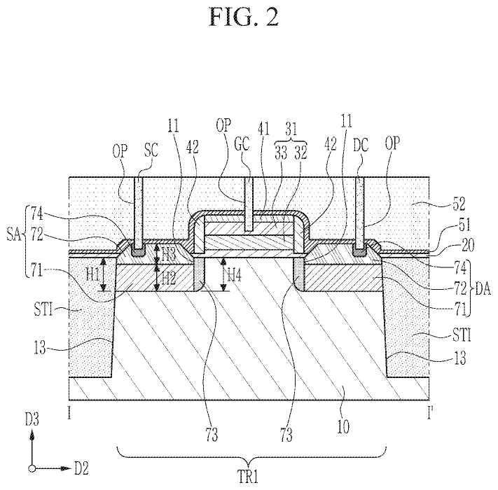

FIG. 1 is a top plan view illustrating a part of a semiconductor device according to an embodiment of the present disclosure. FIG. 2 is a cross-sectional view of a part of a semiconductor device according to an embodiment of the present disclosure, taken along line I-I′ of FIG. 1.

Referring to FIGS. 1 and 2, an isolation layer STI defining an active region ACT may be positioned on a semiconductor substrate 10.

The semiconductor substrate 10 may be one of a material having semiconductor characteristics (e.g., a silicon (Si) wafer), a semiconductor covered by an insulating material, or a semiconductor embedded with a conducting material. The semiconductor substrate 10 may be a silicon (Si) substrate, a germanium (Ge) substrate, a silicon on insulator (SOI) substrate, or a germanium on insulator (GOI) substrate. Alternatively, the semiconductor substrate 10 may include a compound semiconductor such as, for example, silicon carbide (SiC), silicon germanium (SiGe), gallium arsenide (GaAs), indium arsenide (InAs), indium antimonide (InSb), lead tellurium (PbTe) compounds, gallium antimonide (GaSb), indium phosphide (InP), or indium gallium arsenide (InGaAs). In an embodiment of the present disclosure, the semiconductor substrate 10 may be a silicon (Si) wafer having a first conductivity type. In addition, the semiconductor substrate 10 may include one or more semiconductor layers or structures and may include active or operable portions of semiconductor devices.

The semiconductor substrate 10 may be doped with impurities having the first conductivity type. For example, when a first transistor TR is an N-type transistor, the semiconductor substrate 10 may include a P-type impurity. Alternatively, when a first transistor TR is a P-type transistor, the semiconductor substrate 10 may include an N-type impurity.

The isolation layer STI may define a plurality of active regions ACT in the semiconductor substrate 10. For example, an isolation trench 13 defining the plurality of active regions ACT may be positioned in the semiconductor substrate 10. The isolation layer STI may fill the isolation trench 13. For example, the active region ACT may correspond to portions of the semiconductor substrate 10 that are surrounded by the isolation layer STI. The isolation layer STI may surround each active region ACT. Each of the active regions ACT may be separated from each other by the isolation layer STI. The isolation layer STI may include an insulating material.

Referring to FIG. 1, the active region ACT defined by the isolation layer STI may be two-dimensionally arranged along a first direction D1 and a second direction D2 crossing each other. For example, each of the active regions ACT may have a bar shape in a plan view. Each active region ACT may have a minor axis in the first direction D1 and a major axis in the second direction D2. The active region ACT may have a predetermined length along a major axis and a predetermined width along a minor axis. Meanwhile, the shape and arrangement of the active region ACT may be variously modified.

A gate electrode 31 may be positioned on the active region ACT of the semiconductor substrate 10. As shown in FIG. 1, a pair of gate electrodes 31 may be positioned on each active region ACT.

The gate electrode 31 may include doped polysilicon (p-Si), metal, conductive metal nitride, conductive metal silicide, conductive metal oxide, or a combination thereof. The gate electrode 31 may include doped polysilicon (p-Si), aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi₂), titanium silicon nitride (TiSiN), tantalum silicide (TaSi₂), tantalum silicon nitride (TaSiN), ruthenium titanium nitride (RuTiN), nickel silicide (NiSi₂), tungsten silicide (WSi₂), cobalt silicide (CoSi₂), iridium oxide (IrOₓ), ruthenium oxide (RuOₓ), or a combination thereof, but the present disclosure is not limited thereto. The gate electrode 31 may include a single layer or multiple layers of the above-mentioned materials. For example, the gate electrode 31 may include a doped polysilicon (p-Si) pattern, a metal silicide pattern, or a metal pattern.

As shown in FIG. 2, the gate electrode 31 may include a first layer 32 and a second layer 33. For example, the first layer 32 may include a doped semiconductor, such as doped polysilicon (p-Si). The second layer 33 may include at least one metal selected from a group including titanium (Ti), tantalum (Ta), tungsten (W), copper (Cu), and aluminum (Al), and may include tungsten (W) as an example. However, these materials are examples and the present disclosure is not limited thereto.

Referring to FIG. 2, a capping pattern 41 may be positioned on the gate electrode 31. The capping pattern 41 may include silicon nitride (Si₃N₄). Gate spacers 42 may be positioned on both sidewalls of the gate electrode 31 and the capping pattern 41. The gate spacer 42 may include silicon oxide (SiO₂). However, this material is an example, and the present disclosure is not limited thereto.

As shown in FIG. 2, a gate insulating layer 20 may be positioned between the gate electrode 31 and the semiconductor substrate 10. The gate insulating layer 20 may have a width larger than that of the gate electrode 31 in the second direction D2. However, this is an example, and the present disclosure is not limited thereto. The gate insulating layer 20 may include a silicon oxide (SiO₂) layer, a silicon oxynitride (SiON) layer, a high dielectric layer having a dielectric constant higher than that of the silicon oxide (SiO₂) layer, or a combination thereof. The high dielectric layer may be a metal oxide or a metal nitride oxide. For example, the high dielectric layer usable as the gate insulating layer 20 may be at least one of hafnium oxide (HfO₂), hafnium silicate (HfSiO₄), hafnium oxynitride (HfON), hafnium silicon oxynitride (HfSiON), hafnium tantalum oxide (Hf₂Ta₂O₉), hafnium titanium oxide (HfTiO₄), hafnium zirconium oxide (HfZrO₄), hafnium aluminum oxide (HfAlO₃), lanthanum oxide (La₂O₃), lanthanum aluminum oxide (LaAlO₃), barium strontium titanium oxide (BaSrTi₂O₆), barium titanium oxide (BaTiO₃), strontium titanium oxide (SrTiO₃), yttrium oxide (Y₂O₃), zirconium oxide (ZrO₂), aluminum oxide (Al₂O₃), or a combination thereof, but the present disclosure is not limited thereto.

In an embodiment of the present disclosure, the gate insulating layer 20 may include a silicon oxide (SiO₂) layer. As another example, the gate insulating layer 20 may include a first insulating layer (e.g., a silicon oxide (SiO₂) layer) and a second insulating layer (e.g., a silicon oxynitride (SiON) layer) sequentially stacked.

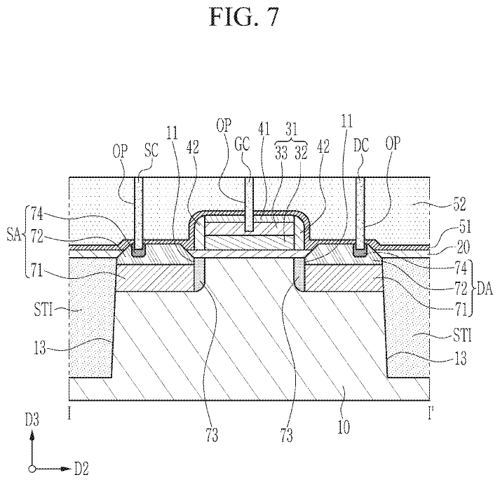

As shown in FIG. 2, the thickness of the gate insulating layer 20 overlapping the gate electrode 31 in a third direction D3 may be greater than the thickness of the gate insulating layer 20 in the part that does not overlap the gate electrode 31. However, this is only an example, and the thickness of the gate insulating layer 20 may be the same in both an overlapping region and a non-overlapping region with the gate electrode 31. A specific modified embodiment will be separately described later with reference to FIG. 7.

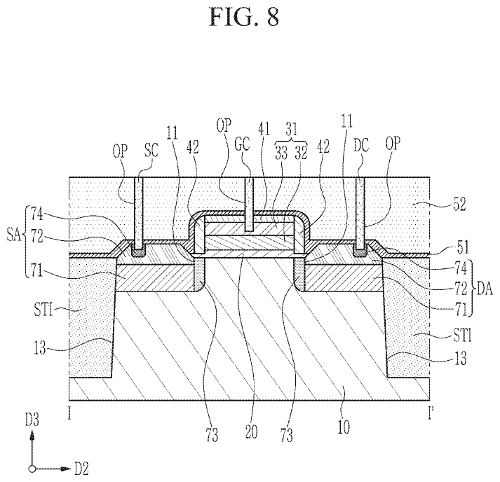

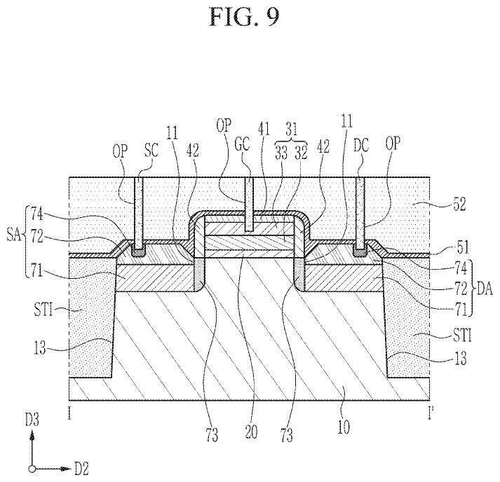

Referring to FIG. 2, the gate insulating layer 20 according to the present embodiment may be positioned to overlap the isolation layer STI. However, the present disclosure is not limited thereto, and, for example, the gate insulating layer 20 may not overlap the isolation layer STI. Further, in an embodiment of the present disclosure, the gate insulating layer 20 may have a planar shape the same as that of the gate electrode 31, and the entire region of the gate insulating layer 20 may be positioned to overlap the gate electrode 31. A specific modified embodiment will be separately described later with reference to FIGS. 8 and 9.

Referring to FIGS. 1 and 2, a source region SA and a drain region DA may be positioned in the active region ACT of the semiconductor substrate 10. In this case, the source region SA and the drain region DA may include a material different from that of the semiconductor substrate 10. For example, the source region SA and the drain region DA may include a material having a bandgap higher than that of the semiconductor substrate 10. For example, the source region SA and the drain region DA may include a material having a bandgap that is 2 to 4 times larger than the bandgap of the material included in the semiconductor substrate 10. For example, when the semiconductor substrate 10 includes silicon (Si), the source region SA and the drain region DA may include at least one of silicon carbide (SiC) or gallium nitride (GaN). Silicon carbide (SiC) may be at least one of 4H-SIC, 6H-SIC, or 3C-SiC. That is, silicon carbide (SiC) may be at least one of 4H-SIC, 6H-SIC having a hexagonal crystal structure, or 3C-SiC having a cubic crystal structure. 4H-SiC consists of an equal number of cubic and hexagonal bonds with a stacking sequences of ABCB. 6H-SiC is composed of two-thirds cubic bonds and one-third hexagonal bonds with a stacking sequences of ABCACB. In which, A, B and C are three configurations of atoms of those stacked layers being arranged.

To be described later, in the semiconductor device according to an embodiment of the present disclosure, since the source region SA and the drain region DA include a material having a bandgap higher than that of the semiconductor substrate 10, the breakdown voltage may increase and the high-voltage driving may be enabled.

As shown in FIGS. 1 and 2, the active region ACT, the source region SA, the drain region DA, and the gate electrode 31 may constitute a first transistor TR1. The first transistor TR1 may be a transistor to which a high-voltage is applied, for example, a transistor to which a voltage of 15V or more is applied.

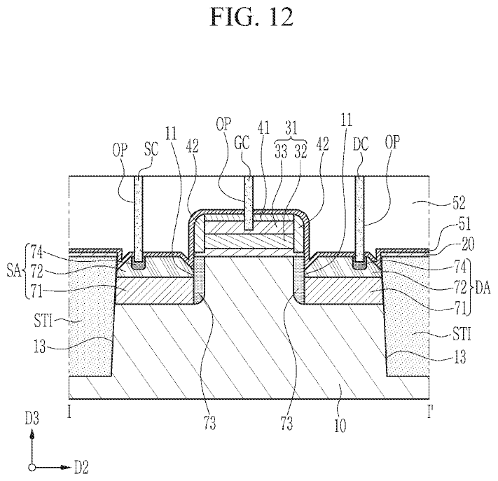

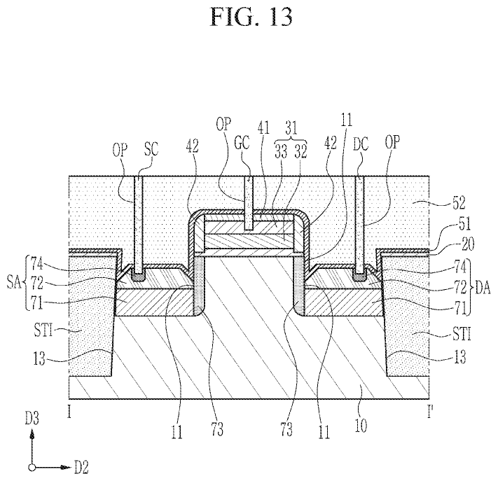

As shown in FIG. 2, the source region SA and the drain region DA may protrude from the semiconductor substrate 10. However, this is only an example, and the present disclosure is not limited thereto. For example, in an embodiment of the present disclosure, upper surfaces of the source region SA and the drain region DA may be positioned on a line the same as that of an upper surface of the semiconductor substrate 10, For example, in an embodiment of the present disclosure, upper surfaces of the source region SA and the drain region DA are positioned below the upper surface of the semiconductor substrate 10. A specific modified embodiment will be separately described later with reference to FIGS. 12 and 13.

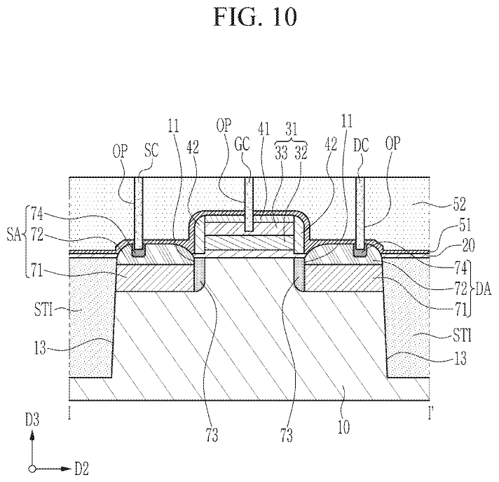

Referring to FIG. 2, the source region SA and the drain region DA may include silicon carbide (SiC), and may be formed by epitaxially growing silicon carbide (SiC). As shown in FIG. 2, since silicon carbide (SIC) is formed by epitaxial growth, the upper surfaces of the source region SA and the drain region DA may have a shape in which the width becomes narrower toward the top. This is a shape resulting from the epitaxial process. As shown in FIG. 2, upper and side surfaces of the source region SA and the drain region DA may form a predetermined angle, but the present disclosure is not limited thereto. For example, according to the epitaxial process, side surfaces and upper surfaces of the source region SA and the drain region DA may be connected in a curved surface without forming an angle. A specific modified embodiment will be separately described later with reference to FIG. 10.

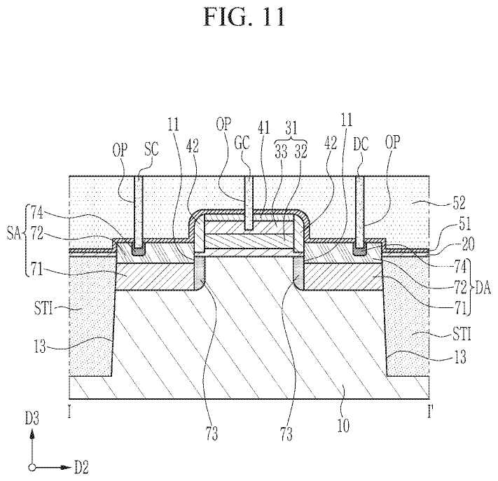

In FIG. 2, the upper surfaces of the source region SA and the drain region DA are shown in a form in which the width becomes narrower toward the top, but this is only an example. The planar area of the source region SA and the drain region DA may be uniform throughout the source region SA and the drain region DA. As an example, when the source region SA and the drain region DA include gallium nitride (GaN), the gallium nitride (GaN) may be formed by a deposition process rather than an epitaxial process, and the planar area of the source region SA and the drain region DA may have a uniform shape throughout the source region SA and the drain region DA. A specific modified embodiment will be separately described later with reference to FIG. 11.

In FIG. 2, the semiconductor substrate 10 may include a trench 11 positioned on each of both sides of the gate electrode 31. The source region SA and the drain region DA may each be formed in the trench 11. In an embodiment of the present disclosure, a formation depth H1 of the trench 11 in the third direction D3 may be in a range from about 100 nm to about 1000 nm. When the formation depth H1 of the trench 11 in the third direction D3 is less than about 100 nm, it may be difficult to adjust the PN junction formed inside the source region SA and the drain region DA. When the formation depth H1 of the trench 11 in the third direction D3 exceeds about 1000 nm, a process of forming the source region SA and the drain region DA may be difficult.

Depending on the formation depth of the trench 11, top surfaces of the source region SA and the drain region DA may protrude from the upper surface of the semiconductor substrate 10, may be positioned on a level the same as that of the upper surface of the semiconductor substrate 10, or may be positioned below the upper surface of the semiconductor substrate 10.

In FIG. 2, the source region SA and the drain region DA may include a first lightly doped region 71 and a second lightly doped region 72. The first lightly doped region 71 may be doped with impurities having a first conductivity type. For example, the first lightly doped region 71 may include P-type impurity. The second lightly doped region 72 may be doped with impurities having a second conductivity type different from the first conductivity type. For example, the second lightly doped region 72 may include N-type impurity. Doping concentration of impurity in the first lightly doped region 71 and the second lightly doped region 72 may be in a range from about 10¹⁵ cm⁻³ to about 10¹⁷ cm⁻³.

As shown in FIG. 2, the first lightly doped region 71 and the second lightly doped region may overlap in the third direction D3. That is, the whole of the first lightly doped region 71 may overlap the whole of the second lightly doped region 72. In this case, the first lightly doped region 71 may be positioned farther from the gate electrode 31 than the second lightly doped region 72 is. For example, as shown in FIG. 2, the first lightly doped region 71 may be positioned at the lower portion of the trench 11 below the second lightly doped region 72.

In FIG. 2, the ratio of a thickness H2 of the first lightly doped region 71 to a thickness H3 of the second lightly doped region 72 may be in a range from about 6:4 to about 8:2. That is, it is preferable that the thickness H2 of the first lightly doped region 71 is greater than the thickness H3 of the second lightly doped region 72. When the thickness of the first lightly doped region 71 is thicker than the thickness of the second lightly doped region 72, an expansion range of the depletion region can be increased, which provides better circumstances for mitigating the electric field.

As shown in FIG. 2, a second impurity doped region 73 may be positioned in the semiconductor substrate 10, which is positioned between the source region SA and the gate electrode 31. The second impurity doped region 73 may be doped with impurities having the second conductivity type. For example, the second impurity doped region 73 may include N-type impurity. For example, the first impurity may be P-type impurity and the second impurity may be N-type impurity. In the second impurity doped region 73, the doping concentration of impurity may be in a range from about 10¹⁵ cm⁻³ to about 10¹⁷ cm⁻³.

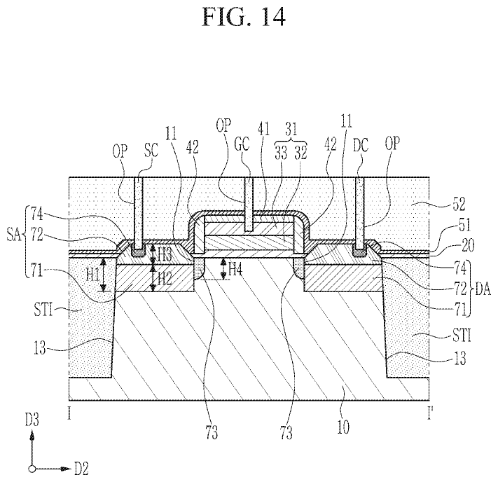

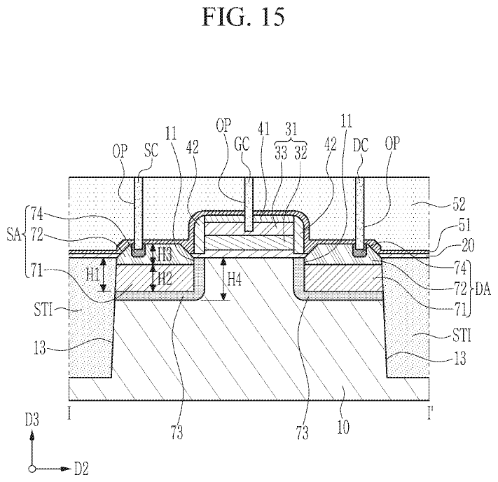

In FIG. 2, a depth H4 of the second impurity doped region 73 is shown to be the same as the formation depth H1 of the trench 11, but this is only an example, and the present disclosure is not limited thereto. The second impurity doped region 73 may have a thickness in the third direction D3 smaller than the formation depth H1 of the trench 11, or may be formed to have a thickness in the third direction D3 greater than the formation depth H1 of the trench 11. As described with reference to FIG. 15 later, when the second impurity doped region 73 is formed to a thickness in the third direction D3 greater than the depth H1 of the trench 11, the second impurity doped region 73 may be positioned to overlap the first lightly doped region 71 and the second lightly doped region 72 in the third direction D3. For example, a portion of the second impurity doped region 73 may be formed under the first lightly doped region 71. A specific modified embodiment will be separately described later with reference to FIGS. 14 to 16.

A width of the second impurity doped region 73 in the second direction D2 may be the same as or similar to a width of the gate spacer 42 in the second direction D2. This is a feature derived from the manufacturing process, and will be separately described later in the manufacturing process.

As shown in FIG. 2, a second heavily doped region 74 may be positioned within the second lightly doped region 72. However, there is no first heavily doped region positioned within the first lightly doped region 71. The second lightly doped region 72 may surround the second heavily doped region 74. The second heavily doped region 74 may be doped with the second conductivity type. The second heavily doped region 74 may include N-type impurity. The doping concentration of the second heavily doped region 74 may be higher than that of the second lightly doped region 72. For example, the doping concentration of the second highly doped region may be 10¹⁹ cm⁻³ to 10²⁰ cm⁻³.

Referring to FIG. 1, the gate electrode 31, the source region SA and the drain region DA are illustrated. As shown in FIG. 2, the first lightly doped region 71 and the second lightly doped region 72 may overlap each other in the third direction D3 in the source region SA and the drain region DA. Referring to FIGS. 1 and 2 simultaneously, the second impurity doped region 73 may be positioned between the gate electrode 31 and the source region SA, and between the gate electrode 31 and the drain region DA. As shown in FIG. 2, the second impurity doped region 73 may not overlap the gate electrode 31 in the third direction D3, but the present disclosure is not limited thereto.

Referring back to FIG. 2, a first interlayer insulating layer 51 may be positioned on the capping pattern 41, and may overlap the gate electrode 31, the gate spacer 42 and the semiconductor substrate 10. The first interlayer insulating layer 51 may include at least one of silicon oxide (SiO₂), silicon oxynitride (SiON), or silicon nitride (Si₃N₄), but the present disclosure is not limited thereto. In an embodiment of the present disclosure, the first interlayer insulating layer 51 may include silicon nitride (Si₃N₄).

A second interlayer insulating layer 52 may be positioned on the first interlayer insulating layer 51. The second interlayer insulating layer 52 may include, for example, at least one of silicon oxide (SiO₂), silicon nitride (Si₃N₄), silicon oxynitride (SiON) or a low dielectric constant (low-k) material having a dielectric constant lower than that of silicon oxide (SiO₂). The low dielectric constant material may include, for example, at least one of flowable oxide (FOX), tonen silazene (TOSZ), undoped silica glass (USG), borosilica glass (BSG), phosphosilica glass (PSG), borophosphosilica glass (BPSG), tetramethyl orthosilicate (TMOS), plasma enhanced tetraethyl orthosilicate (PETEOS), fluorinated tetraethyl orthosilicate (FTEOS), fluoride silicate glass (FSG), carbon doped silicon oxide (CDO), xerogels, aerogels, amorphous fluorinated carbon (a-CFₓ), organo silicate glass (OSG), hydrogen silsesquioxane (HSQ), octamethylcyclotetrasiloxane (OMCTS), hexamethyldisiloxane (HMDS), tris (trimethylsilyl) borate (TMSB), diacetoxyditertiarybutosiloxane (DADBS), tris (trimethylsilyl) phosphate (TMSP), polytetrafluoroethylene (PTFE), parylene, bisbenzocyclobutenes (BCB), SILK, polyimide, porous polymeric material or combinations thereof, but the present disclosure is not limited thereto. In an embodiment of the present disclosure, the second interlayer insulating layer 52 may include an ultralow k dielectric material which includes silicon (Si), carbon (C), oxygen (O) and hydrogen (H), and a multiplicity of nanometer-sized pores.

Depending on embodiments, one of the first interlayer insulating layer 51 and the second interlayer insulating layer 52 may be omitted. That is, depending on embodiments, the first interlayer insulating layer 51 may be positioned alone or the second interlayer insulating layer 52 may be positioned alone.

The gate insulating layer 20, the first interlayer insulating layer 51, and the second interlayer insulating layer 52 may each include an opening OP. The openings OP may respectively be formed to overlap the source region SA, the drain region DA, and the gate electrode 31 in the third direction D3. FIG. 1 shows the openings OP respectively formed to overlap each of the source region SA, the drain region DA, and the gate electrode 31. Referring to FIG. 2, a source contact SC, a drain contact DC, and a gate contact GC may be positioned in each opening OP, respectively.

Each of the source contact SC, drain contact DC, and gate contact GC may include a metal such as aluminum (Al), copper (Cu), or tungsten (W), but the present disclosure is not limited thereto. In an embodiment of the present disclosure, the source contact SC, the drain contact DC, and the gate contact GC may be formed through the same process. For example, the source contact SC, the drain contact DC, and the gate contact GC may include the same material.

Referring to FIG. 2, the source contact SC may contact the source region SA. As shown in FIG. 2, the source contact SC may contact the second heavily doped region 74 of the source region SA. As shown in FIG. 2, the opening OP extends to the source region SA, and the source contact SC may contact the source region SA at the opening OP. That is, the lower and side surfaces of the source contact SC may contact the source region SA. However, depending on embodiments, the opening OP may not extend into the source region SA. In this case, the lower surface of the source contact SC may contact the upper surface of the source region SA. For example, the source contact SC may not extend below the bottom surface of the first interlayer insulating layer 51.

Similarly, the drain contact DC may contact the drain region DA. As shown in FIG. 2, the drain contact DC may contact the second heavily doped region 74 of the drain region DA. As shown in FIG. 2, the opening OP extends to the drain region DA, and the drain contact DC may contact the drain region DA at the opening OP. That is, the lower and side surfaces of the drain contact DC may contact the source region SA. However, depending on embodiments, the opening OP may not extend into the drain region DA. In this case, the lower surface of the drain contact DC may contact the upper surface of the drain region DA. For example, the drain contact DC may not extend below the bottom surface of the first interlayer insulating layer 51.

The gate contact GC may contact the gate electrode 31. As shown in FIG. 2, the gate contact GC may contact the second layer 33 of the gate electrode 31. The opening OP extends to the second layer 33 of the gate electrode 31, and the gate contact GC may contact the second layer 33 of the gate electrode 31 at the opening OP. That is, the lower and side surfaces of the gate contact GC may contact the second layer 33. However, depending on embodiments, the opening OP may not extend to the second layer 33 of the gate electrode 31. In this case, the lower surface of the gate contact GC may contact the upper surface of the second layer 33 of the gate electrode 31. For example, the gate contact GC may not extend below the bottom surface of the capping pattern 41

As described above, in the semiconductor device according to an embodiment of the present disclosure, the source region SA and the drain region DA may include a material having a bandgap higher than that of the semiconductor substrate 10, for example, may include silicon carbide (SiC) or gallium nitride (GaN). The first lightly doped region 71 and the second lightly doped region 72 overlapping in the third direction D3 perpendicular to an upper surface of the semiconductor substrate 10 are formed in the source region SA and the drain region DA, and the first lightly doped region 71 and the second lightly doped region 72 form a PN junction.

As described above, the semiconductor device according to an embodiment of the present disclosure may include a material having a bandgap higher than that of the semiconductor substrate 10 in the source region SA and the drain region DA, and thus breakdown voltage may increase and high-voltage driving may be enabled. A voltage of 15V or more may be applied to the transistor TR1 including the source region SA, the drain region DA, and the gate electrode 31 according to an embodiment of the present disclosure.

Next, various modified embodiments will be described below.

In the previous example, it is shown that each of the openings OP respectively overlapping each of the source region SA, the drain region DA and the gate electrode 31 extends into each of the source region SA, the drain region DA and the gate electrode 31, respectively. However, this is only one example and the present disclosure is not limited thereto.

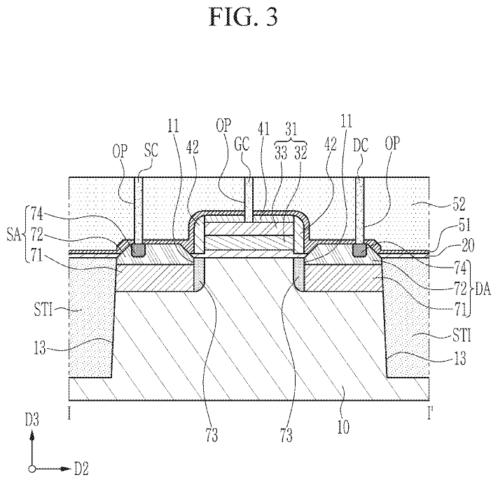

FIG. 3 is a diagram illustrating the same region as FIG. 2 for an embodiment of the present disclosure. Referring to FIG. 3, the semiconductor device according to an embodiment of the present disclosure is similar to the embodiment of FIG. 2 except that each of the openings OP does not respectively extend into each of the source region SA, the drain region DA and the gate electrode 31. A detailed description of the same constituent element is omitted. In the semiconductor device according to the embodiment of FIG. 3, the source contact SC contacts the source region SA on the upper surface of the source region SA, the drain contact DC contacts the drain region DA on the upper surface of the drain region DA, and the gate contact GC may contact the second layer 33 on the upper surface of the second layer 33 of the gate electrode 31.

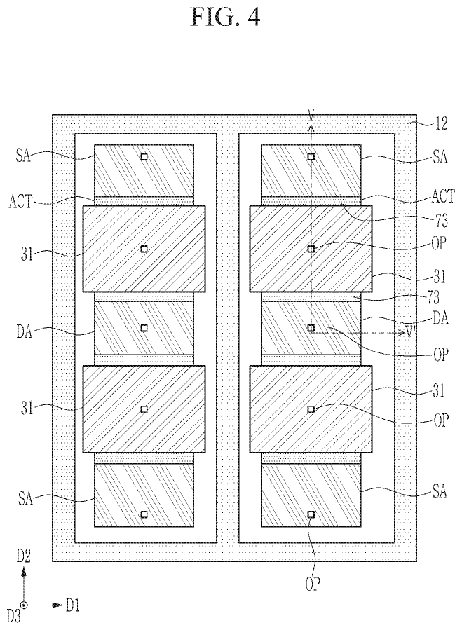

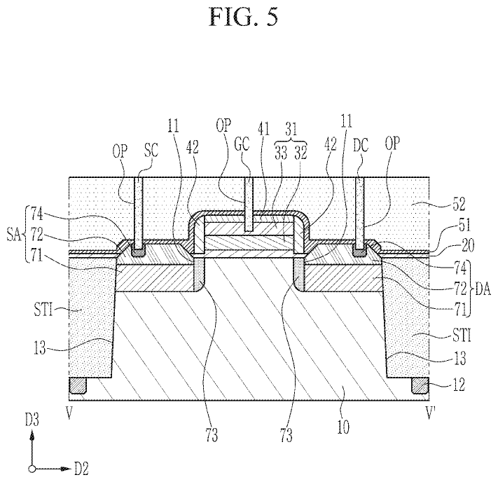

FIG. 4 is a diagram illustrating the same region as FIG. 1 for an embodiment of the present disclosure. FIG. 5 is a cross-sectional view taken along line V-V′ of FIG. 4. Referring to FIGS. 4 and 5, the semiconductor device according to an embodiment of the present disclosure may further include an isolation impurity region 12.

The isolation impurity region 12 may be formed in the semiconductor substrate 10. In addition, the isolation impurity region 12 may overlap the isolation layer STI in the third direction D3. That is, the isolation impurity region 12 may be formed in the semiconductor substrate 10 overlapping the isolation layer STI. In an embodiment of the present disclosure, referring to FIG. 5, the upper surface of the isolation impurity region 12 may contact the lower surface of the isolation layer STI.

The isolation impurity region 12 may be doped with impurities having the first conductivity type. For example, the isolation impurity region 12 may include P-type impurity. The P-type impurity may include, for example, boron (B) or aluminum (Al), but the present disclosure is not limited thereto. In an embodiment of the present disclosure, the isolation impurity region 12 may include boron (B). Accordingly, the isolation impurity region 12 may form a potential barrier between each active region ACT.

In an embodiment of the present disclosure, a doping concentration of the isolation impurity region 12 may be higher than a doping concentration of the semiconductor substrate 10. For example, the semiconductor substrate 10 may include a P-type impurity at a first doping concentration, and the isolation impurity region 12 may include a P-type impurity at a second doping concentration higher than the first doping concentration.

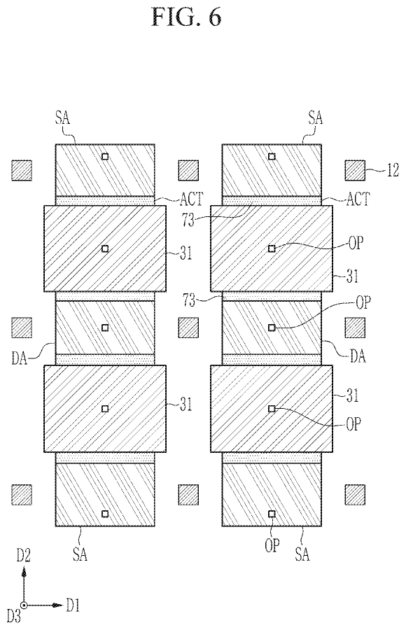

Referring to FIG. 4, the isolation impurity region 12 may completely surround each active region ACT. However, in an embodiment of the present disclosure, the isolation impurity region 12 may not completely surround the active region ACT. FIG. 6 is a diagram illustrating the same region as FIG. 4 for an embodiment of the present disclosure different from the embodiment illustrated in FIG. 4. Referring to FIG. 6, the semiconductor device according to an embodiment of the present disclosure is the same as that of FIG. 4 except that the isolation impurity region 12 does not completely surround the active region ACT. A detailed description of the same constituent element is omitted. That is, as shown in FIG. 6, the isolation impurity region 12 may be positioned in the form of a plurality of islands spaced apart from each other.

FIGS. 4 to 6 each shows an embodiment further including the isolation impurity region 12 in the embodiment of FIG. 2. Hereinafter, modified embodiments having various shapes of the gate insulating layer 20 will be described with reference to FIGS. 7 to 9.

FIG. 7 is a diagram illustrating the same region as FIG. 2 for an embodiment of the present disclosure. Referring to FIG. 7, the semiconductor device according to an embodiment of the present disclosure is the same as that of FIG. 2 except that the thickness of the gate insulating layer 20 is the same in both the region overlapping the gate electrode 31 and the region not overlapping the gate electrode 31. A detailed description of the same constituent element is omitted.

FIG. 8 is a diagram illustrating the same region as FIG. 2 for an embodiment of the present disclosure. Referring to FIG. 8, the semiconductor device according to an embodiment of the present disclosure is the same as that of FIG. 2 except that the gate insulating layer 20 does not overlap the isolation layer STI in the third direction D3. A detailed description of the same constituent element is omitted.

FIG. 9 is a diagram illustrating the same region as FIG. 2 for an embodiment of the present disclosure. Referring to FIG. 9, the semiconductor device according to an embodiment of the present disclosure is the same as that of FIG. 2 except that the gate insulating layer 20 has the same planar shape as the gate electrode 31. A detailed description of the same constituent element is omitted. For example, as shown in FIG. 9, the entire region of the gate insulating layer 20 may overlap the gate electrode 31. In FIG. 2, two side portions of the gate insulating layer 20 under the gate electrode 31 are not overlapped with the gate electrode 31, while in FIG. 6, the gate insulating layer 20 does not have these two side portions. For example, in FIG. 9, the gate insulating layer 20 is not formed above the second impurity doped region 73 to vertically overlap the second impurity doped region 73 in the third direction D3. This is a structure that can be derived when the gate insulating layer 20 is simultaneously etched in the etching process for forming the gate electrode 31.

As described above, FIGS. 7 to 9 are examples in which the shape of the gate insulating layer 20 is different from that of FIG. 2. The specific shapes of the gate insulating layer 20 shown in FIGS. 7 to 9 may vary depending on manufacturing processes, and may be transformed into shapes not shown in FIGS. 7 to 9.

In FIG. 2, the source region SA and the drain region DA have a structure that becomes narrower in width toward the upper surface, and the upper surface of each of the source region SA and the drain region DA protrudes in the third direction D3 from the upper surface of the semiconductor substrate 10. But this is only an example, and the present disclosure is not limited thereto. For example, the shape of the source region SA and the drain region DA may vary.

Hereinafter, various shapes of the source region SA and the drain region DA will be described with reference to FIGS. 10 to 13.

FIG. 10 is a diagram illustrating the same region as FIG. 2 for an embodiment of the present disclosure. Referring to FIG. 10, the semiconductor device according to an embodiment of the present disclosure is the same as that of FIG. 2 except for the upper surface shapes of the source region SA and the drain region DA. A detailed description of the same constituent element is omitted. Referring to FIG. 10, the upper surfaces of the source region SA and the drain region DA may have curved surfaces, and may have shapes connected by curved surfaces without forming an angle between the side surfaces and the upper surfaces. That is, according to the epitaxial process, side surfaces and upper surfaces of the source region SA and the drain region DA may be connected in a curved surface without forming an angle. In other words, with the epitaxial process, the upper corners of the source region SA and the drain region DA may have a rounded shape.

FIG. 11 is a diagram illustrating the same region as FIG. 2 for an embodiment of the present disclosure. Referring to FIG. 11, the semiconductor device according to an embodiment of the present disclosure is the same as that of FIG. 2 except for the upper surface shapes of the source region SA and the drain region DA. A detailed description of the same constituent element is omitted. Referring to FIG. 11, in the semiconductor device according to an embodiment of the present disclosure, the planar areas of the source region SA and the drain region DA may have an overall uniform shape. That is, in the embodiment of FIG. 2, the upper surfaces of the source region SA and the drain region DA have a shape that becomes narrower in width toward the top, but in the embodiment of FIG. 11, the planar areas of the source region SA and the drain region DA may have an overall uniform shape. In this case, the source region SA and the drain region DA of FIG. 11 may include gallium nitride (GaN). That is, in the case of SiC formed by epitaxial growth, due to the characteristics of the epitaxial growth process, the upper surfaces of the source region SA and the drain region DA may have a shape in which the planar area becomes narrower toward the upper surface, as shown in FIG. 2 or FIG. 10. However, gallium nitride (GaN) may be formed through a deposition process rather than epitaxial growth, and in this case, the source region SA and the drain region DA having shapes as shown in FIG. 11 may be formed.

FIG. 12 is a diagram illustrating the same region as FIG. 2 for an embodiment of the present disclosure. Referring to FIG. 12, the semiconductor device according to an embodiment of the present disclosure is the same as that of FIG. 2 except that the top surfaces of the source region SA and the drain region DA are positioned on the same line as the upper surface of the semiconductor substrate 10. A detailed description of the same constituent element is omitted. That is, in the case of the embodiment of FIG. 2, the top surfaces of the source region SA and the drain region DA protrude from the upper surface of the semiconductor substrate 10 in the third direction D3. But in the embodiment of FIG. 12, the top surfaces of the source region SA and the drain region DA may be positioned on a line the same as that of the upper surface of the semiconductor substrate 10. In other words, the top surfaces of the source region SA and the drain region DA may be located at a level or a height the same as that of the upper surface of the semiconductor substrate 10. This can be derived by adjusting the formation depth H1 of the trench 11 positioned on the semiconductor substrate 10.

FIG. 13 is a diagram illustrating the same cross-section as FIG. 2 for an embodiment of the present disclosure. Referring to FIG. 13, the semiconductor device according to an embodiment of the present disclosure is the same as the embodiment of FIG. 2 except that the top surfaces of the source region SA and the drain region DA are positioned below the upper surface of the semiconductor substrate 10. A detailed description of the same constituent element is omitted. That is, in the case of the embodiment of FIG. 2, the top surfaces of the source region SA and the drain region DA protrude from the upper surface of the semiconductor substrate 10. But in the embodiment of FIG. 13, the top surfaces of the source region SA and the drain region DA may be positioned below the upper surface of the semiconductor substrate 10. This can be derived by adjusting the formation depth H1 of the trench 11 positioned on the semiconductor substrate 10.

As described above, the embodiments of FIGS. 10 to 13 are embodiments in which the source region SA and the drain region DA vary in shape. As shown in FIGS. 10 to 13, the shape of the source region SA and the drain region DA and their positional relationship with the semiconductor substrate 10 may vary depending on embodiments. For example, the specific shapes of the source region SA and the drain region DA and specific positional relationship of the source region SA and the drain region DA with the semiconductor substrate 10 may vary depending on the manufacturing processes chosen.

In FIG. 2, the depth H4 of the second impurity doped region 73 is shown to be the same as the formation depth H1 of the trench 11. But this is only an example, and the present disclosure is not limited thereto. The second impurity doped region 73 may have a thickness in the third direction D3 smaller than the formation depth H1 of the trench 11 or may be formed to have a thickness in the third direction D3 greater than the formation depth H1 of the trench 11, or the second impurity doped region 73 may be omitted. Hereinafter, various modified embodiments of the second impurity doped region 73 will be described with reference to FIGS. 14 to 16.

FIG. 14 is a diagram illustrating the same cross-section as FIG. 2 for an embodiment of the present disclosure. Referring to FIG. 14, the semiconductor device according to an embodiment of the present disclosure is the same as the embodiment of FIG. 2 except for the formation depth H4 of the second impurity doped region 73. A detailed description of the same constituent element is omitted. In the embodiment of FIG. 2, the depth H4 of the second impurity doped region 73 is the same as the formation depth H1 of the trench 11. But, in the embodiment of FIG. 14, the depth H4 of the second impurity doped region 73 may be smaller than the formation depth H1 of the trench 11.

FIG. 15 is a diagram illustrating the same cross-section as FIG. 2 for an embodiment of the present disclosure. Referring to FIG. 14, the semiconductor device according to an embodiment of the present disclosure is the same as the embodiment of FIG. 2 except for the depth H4 of the second impurity doped region 73. A detailed description of the same constituent element is omitted. In the embodiment of FIG. 2, the depth H4 of the second impurity doped region 73 is the same as the formation depth H1 of the trench 11. But, in the embodiment of FIG. 14, the depth H4 of the second impurity doped region 73 may be deeper than the formation depth H1 of the trench 11. Therefore, as shown in FIG. 15, the second impurity doped region 73 may overlap the first lightly doped region 71 and the second lightly doped region 72 in the third direction D3. For example, a portion of the second impurity doped region 73 may be formed under the first lightly doped region 71.

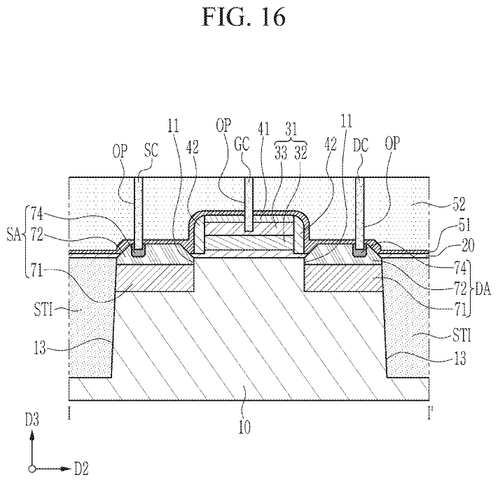

FIG. 16 is a diagram illustrating the same cross-section as FIG. 2 for an embodiment of the present disclosure. Referring to FIG. 16, the semiconductor device according to an embodiment of the present disclosure is the same as the embodiment of FIG. 2 except that the second impurity doped region 73 is not included. A detailed description of the same constituent element is omitted.

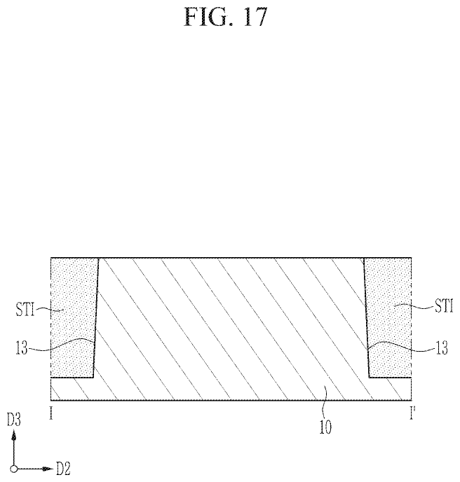

Hereinafter, a method of manufacturing a semiconductor device according to an embodiment of the present disclosure will be described with reference to the drawings. The following manufacturing method is described using the semiconductor device according to the embodiment of FIG. 2 as an example, but the same or similar manufacturing method may be applied to the semiconductor device according to the embodiments of FIGS. 3 to 16. FIGS. 17 to 31 are cross-sectional views for explaining a method of manufacturing a semiconductor device according to an embodiment of the present disclosure.

First, referring to FIG. 17, the isolation layer STI defining an active region is formed on the semiconductor substrate 10. The forming process of the isolation layer STI may include a process of forming the isolation trench 13 by patterning the semiconductor substrate 10 and a process of filling the isolation trench 13 with an insulating material. The patterning process may include a photolithography process and an etch process. The isolation layer STI may be formed by physical vapor deposition (PVD) or chemical vapor deposition (CVD).

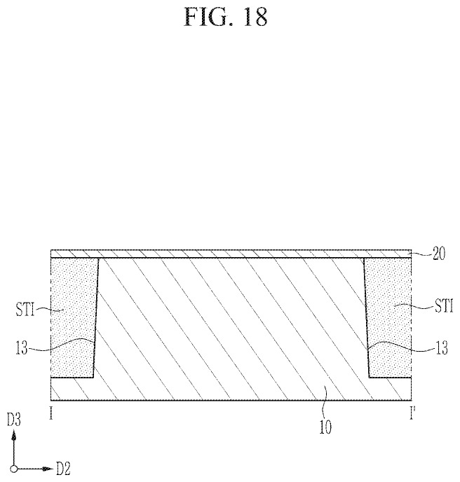

Referring to FIG. 18, the gate insulating layer 20 is formed on the semiconductor substrate 10 and on the isolation layer STI. The gate insulating layer 20 may be formed of a silicon oxide (SiO₂) layer, a silicon oxynitride (SiON) layer, a high-dielectric layer having a dielectric constant higher than that of the silicon oxide (SiO₂) layer, or a combination thereof.

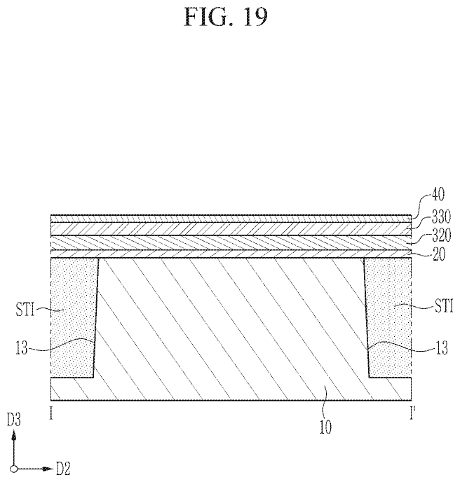

Referring to FIG. 19, a first gate conductive layer 320, a second gate conductive layer 330 and a mask layer 40 are formed on the gate insulating layer 20. The first gate conductive layer 320 may be a polysilicon (p-Si) layer doped with impurity. The second gate conductive layer 330 may include at least one metal selected from a group including titanium (Ti), tantalum (Ta), tungsten (W), copper (Cu), and aluminum (Al). For example, the second gate conductive layer 330 may include tungsten (W). The mask layer 40 may include silicon nitride (Si₃N₄). The gate insulating layer 20, the first gate conductive layer 320, the second gate conductive layer 330, the mask layer 40, and many different layers described hereinafter may be formed through a deposition process such as, for example, a physical vapor deposition (PVD) process, an atomic layer deposition (ALD) process, a chemical vapor deposition (CVD) process, or a combination thereof. However, the present disclosure is not limited thereto.

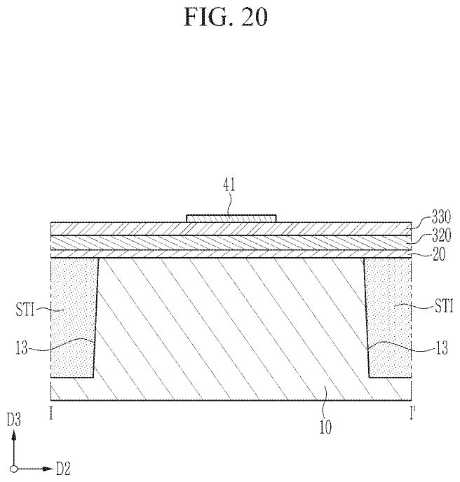

Next, referring to FIG. 20, the capping pattern 41 is formed by patterning the mask layer 40.

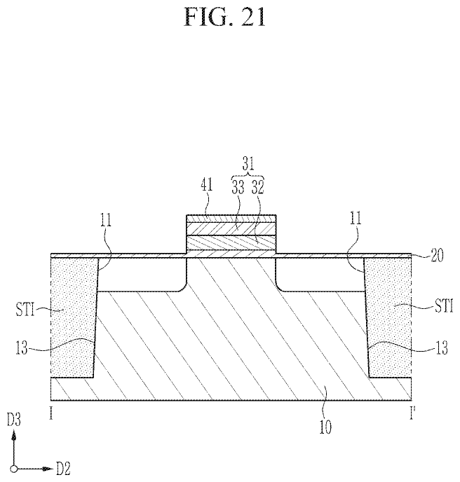

Next, referring to FIG. 21, the first gate conductive film 320, the second gate conductive film 330 are etched using the capping pattern 41 as an etch mask to form the gate electrode 31 including the first layer 32 and the second layer 33. In this etching process, the gate insulating layer 20 may be etched on both sides of the gate electrode 31 to reduce its thickness on both sides of the gate electrode 31. Accordingly, the thickness of the gate insulating layer 20 overlapping the gate electrode 31 may be greater than the thickness of the gate insulating layer 20 not overlapping the gate electrode 31.

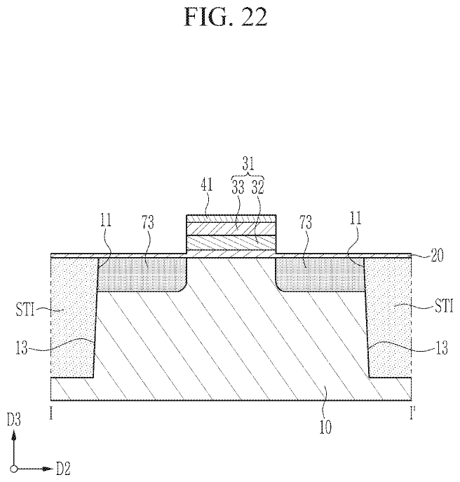

Referring to FIG. 22, the second impurity doped region 73 is formed by doping impurity of the second conductivity type into the semiconductor substrate 10 on both sides of the gate electrode 31. For example, the second impurity doped region 73 may be doped with N-type impurity such as, for example, phosphorus (P) or arsenic (As). The N-type impurities may be injected or implanted into the semiconductor substrate through, for example, an ion implantation process.

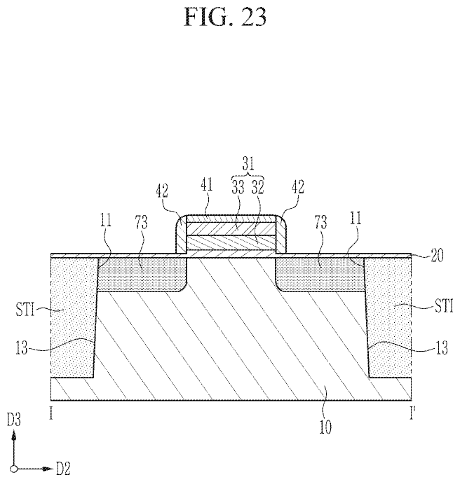

Next, referring to FIG. 23, the gate spacers 42 are formed on both sides of the gate electrode 31 and the capping pattern 41. The gate spacer 42 may include silicon oxide (SiO₂).

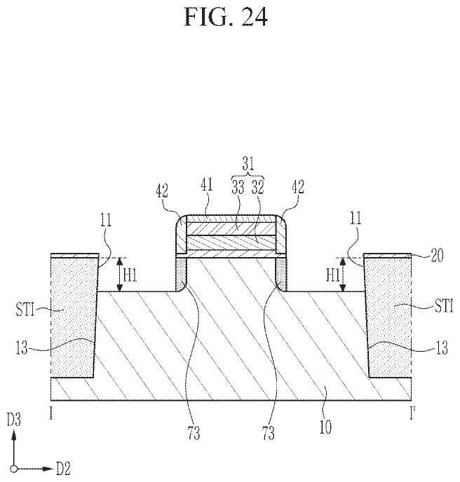

Next, referring to FIG. 24, the trench 11 may be formed by etching the semiconductor substrate 10 positioned on both sides of the gate electrode 31 and the gate spacer 42. For example, the gate insulating layer 20 and the second impurity doped region 73 positioned on both sides of the gate spacer 42 may be etched in this process. In this case, the formation depth H1 of the trench 11 in the third direction D3 may be in a range from about 100 nm to about 1000 nm. By forming the trench 11, a part of the second impurity doped region 73 formed in the previous step may be removed as well. However, in a region overlapping the gate spacer 42 of the semiconductor substrate 10 in the third direction D3, the second impurity doped region 73 may remain without being removed. Therefore, the width of the second impurity doped region 73 in the second direction D2 may be the same as the width of the gate spacer 42 in the second direction D2.

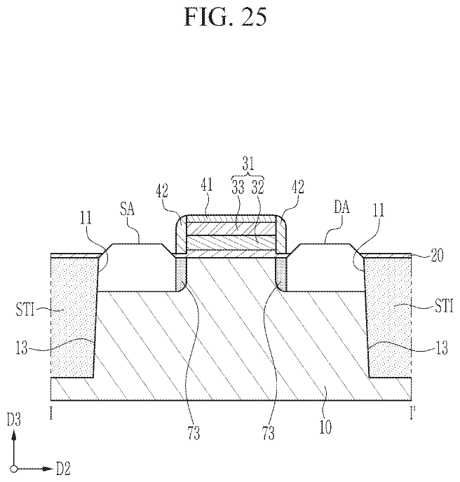

Next, referring to FIG. 25, the source region SA and the drain region DA are formed in the trench 11. In this case, the description of the source region SA and the drain region DA is the same as described above. That is, the source region SA and the drain region DA may include a material having a bandgap higher than that of the semiconductor substrate 10, for example, may include silicon carbide (SiC) or gallium nitride (GaN). Silicon carbide (SiC) may be at least of 4H-SIC, 6H-SIC or 3C-SiC.

When the source region SA and the drain region DA include silicon carbide (SiC), silicon carbide (SiC) may be formed by epitaxial growth. For example, the source region SA and the drain region DA may be formed by performing a selective epitaxial growth (SEG) process using the surfaces of the semiconductor substrate 10 within the trench 11 as a seed layer. For example, the SEG process may include a chemical vapor deposition (CVD) process or a molecular beam epitaxy (MBE) process. Accordingly, as shown in FIG. 25, the width may be narrowed toward the upper surfaces of the source region SA and the drain region DA. When the source region SA and the drain region DA include gallium nitride (GaN), they may be formed through a deposition process. In this case, the source region SA and the drain region DA may be formed in the shape shown in FIG. 11.

In this embodiment, the upper surfaces of the source region SA and the drain region DA are shown as protruding from the upper surface of the semiconductor substrate 10, but this is only an example, and the present disclosure is not limited thereto.

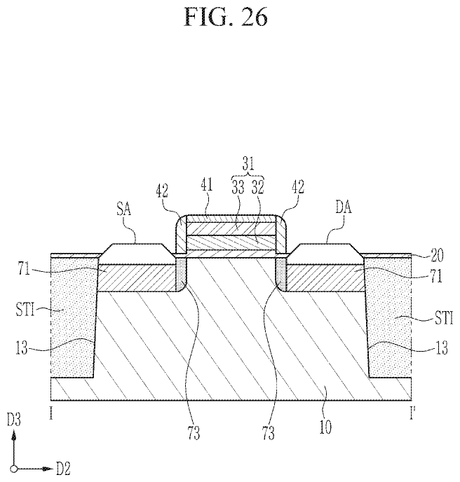

Next, referring to FIG. 26, the first lightly doped region 71 is formed by doping the source region SA and the drain region DA with a first conductivity type impurity. The first conductivity type impurity may be a P-type impurity such as, for example, boron (B) or aluminum (Al) g. In this case, the first lightly doped region 71 may be formed in the lower portions of the source region SA and the drain region DA by applying a first voltage during doping. The first voltage may be, for example, in a range from about 40 keV to about 60 keV. The doping concentration of the first lightly doped region 71 may be in a range from about 10¹⁵ cm⁻³ to about 10¹⁷ cm⁻³.

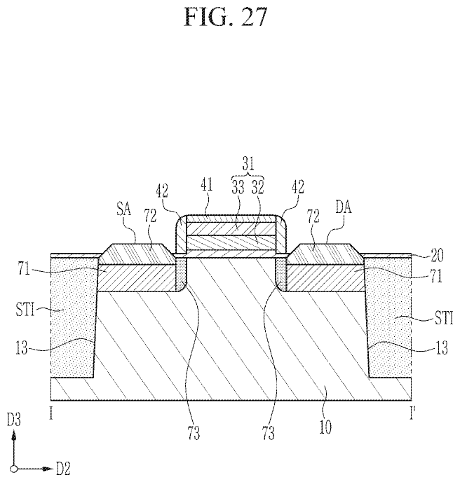

Next, referring to FIG. 27, the second lightly doped region 72 is formed by doping the source region SA and the drain region DA with the second conductivity type impurity. The second conductivity type impurity may be an N-type impurity. In this case, the second lightly doped region 72 may be formed on the first lightly doped region 71 by adjusting the doping length by applying a second voltage lower than the first voltage during doping in this step. For example, the second voltage may be in a range from about 10 keV to about 20 keV. As shown in FIG. 27, the first lightly doped region 71 and the second lightly doped region 72 may be formed to overlap in the third direction D3 by differentiating voltages applied during doping of the first conductivity type impurity and doping of the second conductivity type impurity. As shown in FIG. 27, a PN junction may be formed between the first lightly doped region 71 and the second lightly doped region 72 while being in contact with each other. The doping concentration of the second lightly doped region 72 may be in a range from about 10¹⁵ cm⁻³ to about 10¹⁷ cm⁻³.

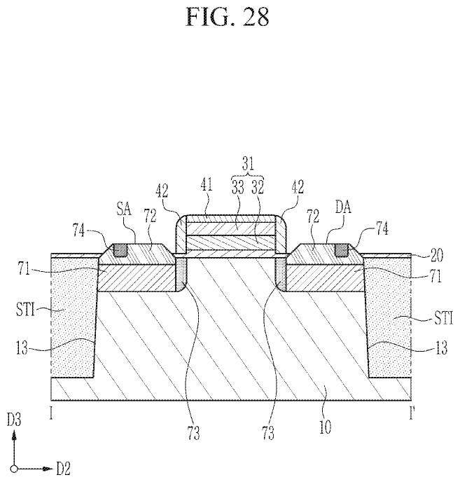

Next, referring to FIG. 28, the second heavily doped region 74 may be formed by doping the second conductivity type impurity into the second lightly doped region 72. The second heavily doped region 74 may include N-type impurity. For example, both the second lightly doped region 72 and the second heavily doped region 74 may include N-type impurity. The doping concentration of the second heavily doped region 74 may be in a range from about 10¹⁹ cm⁻³ to about 10²⁰ cm⁻³. The second heavily doped region 74 may be formed in a partial region of the second lightly doped region 72, and the second highly doped region 74 may be surrounded by the second lightly doped region 72.

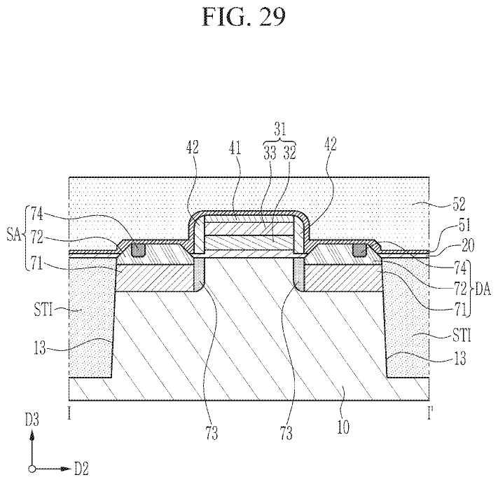

Next, referring to FIG. 29, the first interlayer insulating layer 51 and the second interlayer insulating layer 52 are formed. The first interlayer insulating layer 51 may include silicon nitride (Si₃N₄). The second interlayer insulating layer 52 may include at least one of silicon oxide (SiO₂), silicon nitride (Si₃N₄), silicon oxynitride (SiON), or a low dielectric constant (low-k) material having a dielectric constant lower than that of silicon oxide (SiO₂). Depending on embodiments, only one of the first interlayer insulating layer 51 and the second interlayer insulating layer 52 may be formed.

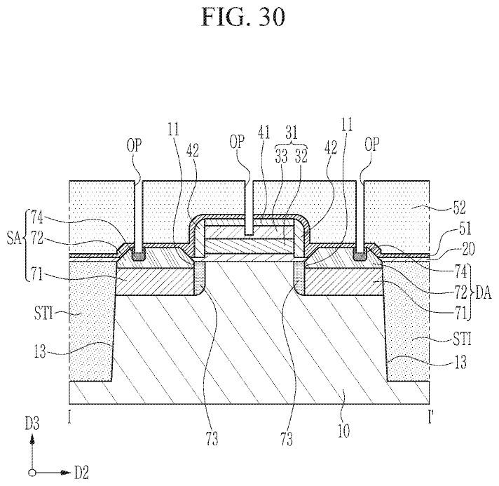

Next, referring to FIG. 30, the openings OP respectively overlapping the source region SA, the drain region DA and the gate electrode 31 are formed at the capping pattern 41, the first interlayer insulating layer 51 and the second interlayer insulating layer 52. As shown in FIG. 30, the openings OP may be formed to extend into the source region SA, the drain region DA and the gate electrode 31, respectively. As shown in FIG. 30, the opening OP positioned to overlap the source region SA may be formed in the second heavily doped region 74 of the source region SA. Similarly, the opening OP overlapping the drain region DA may be formed in the second heavily doped region 74 of the drain region DA. The opening OP overlapping the gate electrode 31 may be formed to penetrate through the second interlayer insulating layer 52, the first interlayer insulating layer 51 and the capping pattern 41 to contact the second layer 33 of the gate electrode 31.

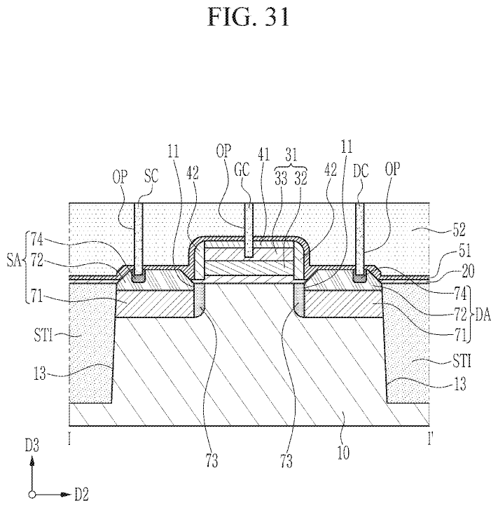

Next, referring to FIG. 31, the source contact SC, the drain contact DC and the gate contact GC are formed by forming metal in each opening OP. Each of the source contact SC, the drain contact DC, and the gate contact GC may include a metal such as aluminum (Al), copper (Cu), or tungsten (W), but the present disclosure is not limited thereto. The source contact SC, the drain contact DC, and the gate contact GC may be formed in the same process and include the same material.

While the above embodiment describes an embodiment in which the second heavily doped region 74 is formed prior to the formation of the opening OP, in other embodiments, the second heavily doped region 74 may be formed after the formation of the opening OP.

In the embodiment described above, a separate mask is required to form the second heavily doped region 74. However, in the case of forming the second heavily doped region 74 by doping through the opening OP after forming the opening OP, no separate mask is required. For example, the second interlayer insulating layer 52 and the first interlayer insulating layer 51 may be used as an ion implantation mask during the ion implantation process by doping through the opening OP formed in the second interlayer insulating layer 52 and the first interlayer insulating layer 51 to form the second heavily doped region 74 in a partial region of the second lightly doped region 72.

Hereinafter, a semiconductor device including a transistor according to an embodiment of the present disclosure will be described with reference to the drawings.

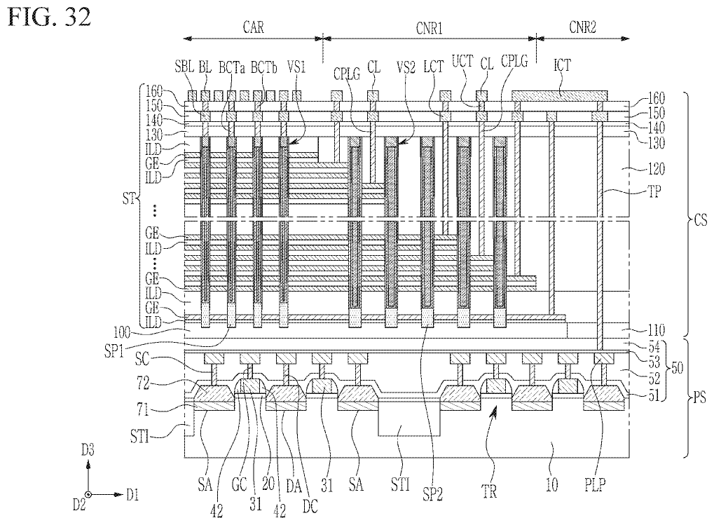

FIG. 32 is a cross-sectional view of a semiconductor device according to an embodiment of the present disclosure. Referring to FIG. 32, the semiconductor device may include a peripheral circuit structure PS and a cell array structure CS on the peripheral circuit structure PS.

The peripheral circuit structure PS may include peripheral circuits integrated on the entire surface of the semiconductor substrate 10, and a lower insulating layer 50 covering the peripheral circuits.

The peripheral circuits may include row and column decoders, a page buffer, a voltage generator, and a control circuit integrated on the semiconductor substrate 10. For example, the peripheral circuits disposed in the peripheral circuit structure PS may be circuits that process data input to or output from the cell array structure CS at high speed. More specifically, the peripheral circuits may include a plurality of transistors TR. The transistor TR may include substantially the same characteristics as the first transistors TR1 described above with reference to FIGS. 1 to 16. A detailed description of the same constituent element is omitted. For example, the transistor TR of the peripheral circuit structure PS may include the gate electrode 31 on the semiconductor substrate 10, the source region SA and the drain region DA positioned on both sides of the gate electrode 31. The source region SA and the drain region DA may include a material having a bandgap higher than that of the semiconductor substrate 10, for example, may include silicon carbide (SiC) or gallium nitride (GaN). The first lightly doped region 71 and the second lightly doped region 72 overlapping in the third direction D3 may be positioned in the source region SA and the drain region DA. The first lightly doped region 71 and the second lightly doped region 72 may form a PN junction.

In an embodiment of the present disclosure, the source contact SC and the drain contact DC of the transistor TR may be electrically connected to electrodes GE as word lines of the cell array structure CS. Also, the transistors TR of the peripheral circuit structure PS may configure a part of the page buffer, and may be electrically connected to bit lines BL.

In FIGS. 32 to 35, the plurality of transistors TR may include other shapes of transistors in addition to the transistors shown in FIGS. 1 to 16. For example, the transistors of FIGS. 1 to 16 may be positioned in regions to which a high-voltage is applied, and transistors of different shapes may be positioned in regions to which a relatively low-voltage is applied, among the semiconductor devices of FIGS. 32 to 35. For example, in a transistor having a different shape, the source region SA and the drain region DA may be regions in which the semiconductor substrate 10 is doped with impurity, without being formed of a separate material different from the semiconductor substrate 10.

The lower insulating layer 50 may be positioned on the entire surface of the semiconductor substrate 10. The lower insulating layer 50 may include interlayer insulating layers stacked in multi-layer. For example, the lower insulating layer 50 may include a silicon oxide (SiO₂) layer, a silicon nitride (Si₃N₄) layer, a silicon oxynitride (SiON) layer, or a low dielectric layer having a dielectric constant lower than that of silicon oxide (SiO₂). For example, the lower insulating layer 50 may include the first interlayer insulating layer 51, the second interlayer insulating layer 52, an etch stop layer 53, and a third interlayer insulating layer 54 sequentially stacked. The etch stop layer 53 may be positioned between the second interlayer insulating layer 52 and the third insulating interlayer 54. The etch stop layer 53 may include an insulating material different from that of the second interlayer insulating layer 52 and the third interlayer insulating layer 54, and may cover an upper surface of a peripheral circuit wire PLP.

The peripheral circuit wires PLP may be electrically connected to the transistor TR through the gate contact GC, the source contact SC, and the drain contact DC.

The cell array structure CS may be positioned on the lower insulating layer 50. The cell array structure CS may include a cell array region CAR, a first connection region CNR1 and a second connection region CNR2. The first connection region CNR1 may be positioned between the cell array region CAR and the second connection region CNR2 in the first direction D1.

The cell array structure CS may include a semiconductor layer 100, a stacking structure ST, a first vertical structure VS1, a second vertical structure VS2, a cell contact plug CPLG, a penetration plug TP, a bit line BL and a cell conductive line CL.

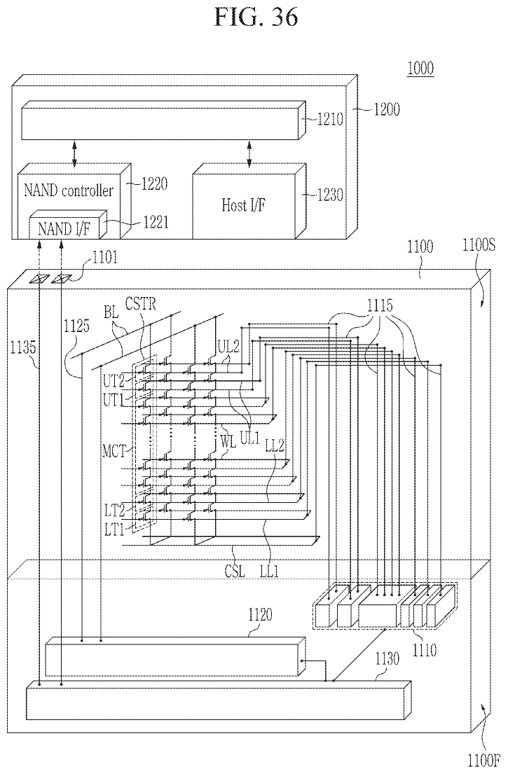

According to an embodiment of the present disclosure, a cell string (CSTR of FIG. 36) shown in FIG. 36 may be integrated on the semiconductor layer 100. The stacking structure ST and the first vertical structure VS1 may configure the cell string (CSTR in FIG. 36) shown in FIG. 36. For example, the stacking structure ST and the first vertical structure VS1 may constitute a plurality of memory cells. In an embodiment of the present disclosure, the cell array structure CS may include memory cells arranged three-dimensionally on the semiconductor layer 100.

The semiconductor layer 100 may be positioned on the upper surface of the lower insulating layer 50. The semiconductor layer 100 may include a semiconductor material, and may also include an insulating material or a conductive material. The semiconductor layer 100 may include a semiconductor doped with dopants, or an intrinsic semiconductor not doped with impurity. The semiconductor layer 100 may have a crystal structure including at least one selected from single crystal, amorphous, and polycrystalline.

A buried insulating layer 110 covering sidewalls of the semiconductor layer 100 may be positioned in the second connection region CNR2. The buried insulating layer 110 may contact the lower insulating layer 50. A bottom surface of the buried insulating layer 110 may be coplanar with a bottom surface of the semiconductor layer 100, but the present disclosure is not limited thereto.

The stacking structure ST may be disposed on the semiconductor layer 100. The stacking structure ST may include electrodes GE and insulating layers ILD alternately stacked along the third direction D3 perpendicular to the upper surface of the semiconductor layer 100.

The stacking structure ST may extend along the first direction D1 from the cell array region CAR to the first connection region CNR1, and may have a stepped structure. For example, the electrodes GE may be staked in a staircase shape in which extension lengths in the first direction D1 may gradually decrease in a stepwise manner from a lowermost level toward an uppermost level. Each of the electrodes GE may include a pad portion contacting the cell contact plugs CPLG. The stepped structure of the stacking structure ST may be modified into various shapes.

The electrodes GE may include, for example, at least one of a doped semiconductor (e.g., doped silicon (Si)), a metal (e.g., tungsten (W), copper (Cu), aluminum (Al)), a conductive metal nitride (e.g., titanium nitride (TiN), tantalum nitride (TaN)), or a transition metal (e.g., titanium (Ti), tantalum (Ta)), and the like. The insulating layers ILD may include a silicon oxide (SiO₂) layer or a low dielectric layer having a dielectric constant lower than that of silicon oxide (SiO₂). According to an embodiment of the present disclosure, the semiconductor device may be a vertical NAND flash memory device. In this case, the electrodes GE of the stacking structure ST may be used as gate lower lines LL1 and LL2, word lines WL, and gate upper lines UL1 and UL2, described later with reference to FIG. 36.

A flat insulating layer 120 may cover the pad portions of the stacking structure ST having a stepped structure. The flat insulating layer 120 may have a substantially flat upper surface. The flat insulating layer 120 may include one insulating layer or a plurality of stacked insulating layers. A first upper insulating layer 130, a second upper insulating layer 140, a third upper insulating layer 150, and a fourth upper insulating layer 160 may be sequentially stacked on the flat insulating layer 120.

The plurality of first vertical structures VS1 may penetrate the stacking structure ST in the cell array region CAR. The first vertical structure VS1 may be arranged in one direction or in a zigzag form when viewed from a plan view.

The second vertical structure VS2 may penetrate the flat insulating layer 120 and the stacking structure ST in the first connection region CNR1. The second vertical structures VS2 may penetrate the pad portions of the electrodes GE.

Each of the first vertical structure VS1 and the second vertical structure VS2 may include a vertical semiconductor pattern, and a data storage pattern surrounding a sidewall of the vertical semiconductor pattern. The data storage pattern may include a tunnel insulating layer, a charge storage layer, and a blocking insulating layer as data storage elements of the NAND flash memory device. The tunnel insulating layer may allow charges to tunnel to the charge storage layer through the process of Fowler-Nordheim (F-N) tunneling. The charge storage layer may be a charge trapping layer.

A first semiconductor pillar SP1 may be positioned between the first vertical structure VS1 and the semiconductor layer 100, and a second semiconductor pillar SP2 may be positioned between the second vertical structure VS2 and the semiconductor layer 100.

The first semiconductor pillar SP1 and the second semiconductor pillar SP2 may penetrate the electrode GE positioned at the bottom layer of the stacking structure ST.

The first semiconductor pillar SP1 and the second semiconductor pillar SP2 may directly contact the semiconductor layer 100, and may include an epitaxial layer grown from the semiconductor layer. The first semiconductor pillar SP1 and the second semiconductor pillar SP2 may electrically connect the vertical semiconductor patterns of the first and second vertical structures VS1 and VS2 to the semiconductor layer 100. The first semiconductor pillar SP1 and the second semiconductor pillar SP2 may be made of silicon (Si). Alternatively, the first semiconductor pillar SP1 and the second semiconductor pillar SP2 may also include germanium (Ge), silicon germanium (SiGe), III-V group semiconductor compound, or II-VI group semiconductor compound.

The cell contact plug CPLG may penetrate the first upper insulating layer 130, the second upper insulating layer 140, and the flat insulating layer 120 and be respectively connected to the pad portion of the electrode GE. Vertical lengths of the cell contact plug CPLG in the third direction D3 may decrease as a distance from the cell array region CAR decreases. In an embodiment of the present disclosure, each of the cell contact plugs CPLG may include a metal silicide pattern, a metal nitride pattern and a metal pattern sequentially stacked on the upper surface of the corresponding one of the electrodes GE. Upper surfaces of the cell contact plugs CPLG may be substantially coplanar. The cell conductive line CL may be positioned on the fourth upper insulating layer 160, and may be connected to the cell contact plug CPLG through a lower contact plug LCT and an upper contact plug UCT.

The bit line BL may be positioned on the fourth upper insulating layer 160, and may intersect the stacking structure ST. The bit line BL may be electrically connected to the first vertical structure VS1 through lower and upper bit line contact plugs BCTa and BCTb. The lower bit line contact plug BCTa and the upper bit line contact plug BCTb may be connected with a sub bit line SBL.

Penetration plugs TP may penetrate the first upper insulating layer 130, the second upper insulating layer 140, the flat insulating layer 120, and the buried insulating layer 110 in the second connection region CNR2 to be connected to the peripheral circuit wire PLP. The penetration plugs TP may be horizontally spaced apart from the stacking structure ST. In an embodiment of the present disclosure, the upper surfaces of the penetration plugs TP and the cell contact plugs CPLG may be substantially coplanar with each other, but the present disclosure is not limited thereto. The penetration plugs TP may be connected to the cell contact plug CPLG through the connection conductive pattern ICT. For example, the transistor TR of the peripheral circuit structure PS may be electrically connected to the electrodes GE of the cell array structure CS through the penetration plugs TP, the connection conductive pattern ICT, and the cell contact plug CPLG.

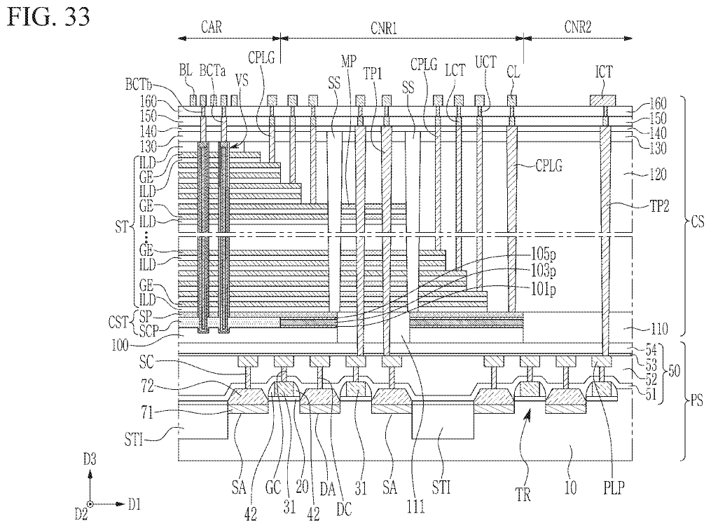

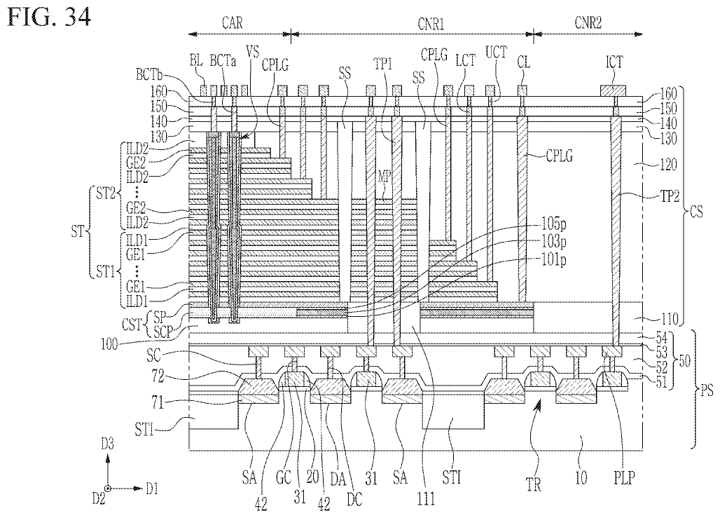

The semiconductor device according to an embodiment of the present disclosure shown in FIGS. 33 and 34 may include the peripheral circuit structure PS and the cell array structure CS, similar to the semiconductor device previously described with reference to FIG. 32. For brevity of description, descriptions to the same technical features as those of the semiconductor device described above with reference to FIG. 32 may be omitted, and differences between the embodiments will be described.

Referring to FIG. 33, as described above, the peripheral circuit structure PS may include the transistor TR. A description of the peripheral circuit structure PS is omitted because it is the same as described above.

According to this embodiment, the cell array structure CS may further include a source structure CST positioned between the semiconductor layer 100 and the stacking structure ST.

The source structure CST may include a source conductive pattern SCP, and a support conductive pattern SP on the source conductive pattern SCP. The source structure CST may be parallel to the upper surface of the semiconductor layer 100, and may extend parallel to the stacking structure ST in the cell array region CAR.

The source conductive pattern SCP may be disposed between the semiconductor layer 100 and the stacking structure ST in the cell array region CAR. In an embodiment of the present disclosure, the source conductive pattern SCP may be formed on the cell array region CAR of the semiconductor layer 100, and may not be formed on the first connection region CNR1 and the second connection region CNR2 of the semiconductor layer 100, but the present disclosure is not limited thereto. The source conductive pattern SCP may be formed of a semiconductor material doped with a second conductivity type dopant (e.g., phosphorus (P) or arsenic (As)). For example, the source conductive pattern SCP may be formed of a polysilicon (p-Si) layer doped with N-type dopants.

The support conductive pattern SP may cover the upper surface of the source conductive pattern SCP in the cell array region CAR, and may cover the upper surface of dummy insulating patterns 101p, 103p, and 105p in the first connection region CNR1. The support conductive pattern SP may include a semiconductor doped with dopants having the second conductivity type (e.g., N-type) or an intrinsic semiconductor not doped with impurity. In an embodiment of the present disclosure, the support conductive pattern SP may include polysilicon (p-Si). In the cell array region CAR, parts of the support conductive pattern SP may penetrate the source conductive pattern SCP and contact the semiconductor layer 100.

According to an embodiment of the present disclosure, a lower penetration insulating pattern 111 penetrating the source structure CST and the semiconductor layer 100 may be positioned in the first connection region CNR1. The lower penetration insulating pattern 111 may contact the lower insulating layer 50.

The dummy insulating patterns 101p, 103p, and 105p may be positioned between the semiconductor layer 100 and the stacking structure ST in the first connection region CNR1. The dummy insulating patterns 101p, 103p, and 105p may include a first insulating pattern 101p, a second insulating pattern 103p, and a third insulating pattern 105p sequentially stacked. The second insulating pattern 103p may include an insulating material different from that of the first insulating pattern 101p and the third insulating pattern 105p. The second insulating pattern 103p may be thicker than the first insulating pattern 101p and the third insulating pattern 105p.

The first insulating pattern 101p, the second insulating pattern 103p, and the third insulating pattern 105p may include at least one of a silicon oxide (SiO₂) layer, a silicon nitride (Si₃N₄) layer, a silicon oxynitride (SiON) layer, a silicon carbide (SiC) layer, or a silicon germanium (SiGe) layer. In an embodiment of the present disclosure, each of the first insulating pattern 101p and the third insulating pattern 105p may include silicon oxide (SiO₂), while the second insulating pattern 103p may include silicon nitride (Si₃N₄).

The buried insulating layer 110 covering sidewalls of the semiconductor layer 100 and the sidewalls of the source structure CST may be positioned in the second connection region CNR2. The buried insulating layer 110 may contact the lower insulating layer 50, and may have an upper surface substantially coplanar with an upper surface of the source structure CST.

According to an embodiment of the present disclosure, the stacking structure ST may include a mold pattern MP positioned at the same level as the electrodes GE in the first connection region CNR1 and disposed between the insulating layers ILD, respectively. The mold pattern MP may include an insulating material different from the insulating layers ILD. The mold pattern MP may include, for example, at least one of a silicon nitride (Si₃N₄) layer, a silicon oxynitride (SiON) layer, or a silicon germanium (SiGe) layer. The mold pattern MP may be closer to the cell array region CAR than the pad portions of the electrodes GE. In addition, the mold patterns MP may overlap the lower penetration insulating pattern 111 in a plan view.

A plurality of vertical structures VS may penetrate the stacking structure ST and the source structure CST in the cell array region CAR. A part of a sidewall of the vertical semiconductor pattern of the vertical structure VS may contact the source conductive pattern SCP. For example, the source conductive pattern SCP may extend through the data storage pattern surrounding the sidewall of the vertical semiconductor pattern, and may contact the side surface of the semiconductor pattern.

A penetration insulating pattern SS may penetrate a part of the stacking structure ST in the first connection region CNR1. The penetration insulating pattern SS may be positioned between the electrode GE and the mold pattern MP. The penetration insulating pattern SS may surround the mold pattern MP in a plan view. The penetration insulating pattern SS may include an insulating layer covering the sidewalls of the stacking structure ST and the sidewalls of the mold pattern MP. The penetration insulating pattern SS may contact the upper surface of the support conductive pattern SP and/or the upper surface of the lower penetration insulating pattern 111.

A first penetration plug TP1 may vertically penetrate the mold pattern MP of the stacking structure ST, the lower penetration insulating pattern 111, the third interlayer insulating layer 54 and the etch stop layer 53 in the first connection region CNR1 to connect to the peripheral circuit wire PLP. The first penetration plug TP1 may be electrically connected to the cell contact plug CPLG through the cell conductive lines CL.

A second penetration plug TP2 may penetrate the first upper insulating layer 130, the second upper insulating layer 140, the flat insulating layer 120, the buried insulating layer 110, the third interlayer insulating layer 54 and the etch stop layer 53 in the second connection region CNR2 to be connected to the peripheral circuit wire PLP.

According to the embodiment shown in FIG. 34, the stacking structure ST on the semiconductor layer 100 may include a first electrode structure ST1 and a second electrode structure ST2 on the first electrode structure ST1. The first electrode structure ST1 may include first electrodes GE1 stacked in a direction vertical to the semiconductor layer 100 (i.e., in the third direction D3). The first electrode structure ST1 may further include a first insulating layer ILD1 separating the stacked first electrodes GE1 from each other. The first insulating layers ILD1 and the first electrodes GE1 of the first electrode structure ST1 may be alternately stacked in the third direction D3. A second insulating layer ILD2 may be positioned on top of the first electrode structure ST1.

The second electrode structure ST2 may include second electrodes GE2 stacked on the first electrode structure ST1 in the third direction D3. The second electrode structure ST2 may further include the second insulating layer ILD2 separating the stacked second electrodes GE2 from each other. The second insulating layers ILD2 and the second electrodes GE2 of the second electrode structure ST2 may be alternately stacked in the third direction D3.

In an embodiment of the present disclosure, each of the vertical structures VS may include a first vertical extension portion penetrating the first electrode structure ST1, a second vertical extension portion penetrating the second electrode structure ST2, and an extension portion located between the first and second vertical extension portions. The extension portion located between the first and second vertical extension portions may be positioned in the top layer of the first insulating layers ILD1. The diameter of the first vertical extension portion of the vertical structure VS may increase toward the extension portion located between the first and second vertical extension portions.

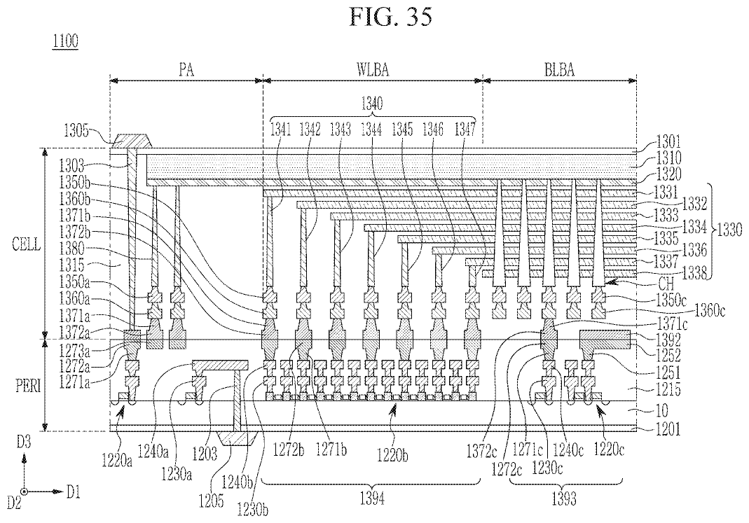

FIG. 35 is a cross-sectional view of a semiconductor device according to an embodiment of the present disclosure.

Referring to FIG. 35, a semiconductor device 1100 may be a chip to chip (C2C) structure. The C2C structure may mean manufacturing an upper chip including a cell array structure CELL on a first wafer, manufacturing a lower chip including a peripheral circuit structure PERI on a second wafer different from the first wafer, and connecting the upper chip and the lower chip to each other by a bonding method. For example, the bonding method may refer to a method of electrically connecting the bonding metal formed on the top metal layer of the upper chip and the bonding metal formed on the top metal layer of the lower chip to each other. For example, when the bonding metal is formed of copper (Cu), the bonding method may be a Cu-to-Cu bonding method, and the bonding metal may also be formed of aluminum (Al) or tungsten (W). In an embodiment of the present disclosure, the upper chip and the lower chip may be connected directly to each other by a hybrid bonding method. For example, when the bonding metal formed on the top metal layer of the upper chip and the bonding metal formed on the top metal layer of the lower chip are formed of copper (Cu), the bonding metal formed on the top metal layer of the upper chip and the bonding metal formed on the top metal layer of the lower chip may be physically and electrically connected to each other by a copper (Cu)-copper (Cu) bonding method. In addition, referring to FIG. 35, a surface of the interlayer insulating layer 1315 of the upper chip and a surface of the interlayer insulating layer 1215 of the lower chip may be bonded to each other by a dielectric material-dielectric material bonding method.

Each of the peripheral circuit structure PERI and cell array structure CELL of the semiconductor device 1100 may include an external pad bonding region PA, a word line bonding region WLBA, and a bit line bonding region BLBA.

The peripheral circuit structure PERI may include the semiconductor substrate 10, a plurality of circuit elements 1220a, 1220b, and 1220c positioned on the semiconductor substrate 10, first metal layers 1230a, 1230b and 1230c connected to the plurality of circuit elements 1220a, 1220b and 1220c, and second metal layers 1240a, 1240b and 1240c formed on the first metal layers 1230a, 1230b and 1230c.

Although the plurality of circuit elements 1220a, 1220b and 1220c are shown in a simplified form for convenience of description in FIG. 35, each of the circuit elements 1220a, 1220b and 1220c may include the first transistor TR1 as previously described with reference to FIGS. 1 to 16.

The plurality of circuit elements 1220a, 1220b and 1220c may include the gate electrode 31 on the semiconductor substrate 10, and the source region SA and the drain region DA positioned on both sides of the gate electrode 31 as shown in FIG. 2. The source region SA and the drain region DA may include a material having a bandgap higher than that of the semiconductor substrate 10, for example, may include silicon carbide (SiC) or gallium nitride (GaN). The first lightly doped region 71 and the second lightly doped region 72 overlapping in the third direction D3 may be positioned in the source region SA and the drain region DA.

In an embodiment of the present disclosure, the first metal layers 1230a, 1230b and 1230c may be formed of tungsten (W) having a relatively high electrical resistivity, and the second metal layers 1240a, 1240b and 1240c may be made of copper (Cu) having a relatively low electrical resistivity.

In this specification, only the first metal layers 1230a, 1230b and 1230c and the second metal layers 1240a, 1240b and 1240c are shown and described, but the present disclosure id not limited thereto. For example, one or more metal layers may be further formed on the second metal layers 1240a, 1240b and 1240c. At least some of the one or more metal layers formed on the second metal layers 1240a, 1240b, and 1240c may be formed of aluminum (Al) or the like, which has a higher electrical resistivity than copper (Cu) forming the second metal layers 1240a, 1240b, and 1240c.

The gate contact GC, the source contact SC, and the drain contact DC described above with reference to FIGS. 1 to 16 may be connected to the first metal layers 1230a, 1230b, and 1230c. Alternatively, the first metal layers 1230a, 1230b, and 1230c may configure the gate contact GC, the source contact SC, and the drain contact DC described above with reference to FIGS. 1 to 16.

An interlayer insulating layer 1215 is disposed on the semiconductor substrate 10 to cover the plurality of circuit elements 1220a, 1220b, and 1220c, the first metal layers 1230a, 1230b, and 1230c, and the second metal layers 1240a, 1240b, and 1240c, and may include an insulating material such as silicon oxide (SiO₂) or silicon nitride (Si₃N₄).

Lower bonding metals 1271b and 1272b may be formed on a second metal layer 1240b of the word line bonding region WLBA. In the word line bonding region WLBA, the lower bonding metals 1271b and 1272b of the peripheral circuit structure PERI may be electrically connected to upper bonding metals 1371b and 1372b of the cell array structure CELL by a bonding method. The lower bonding metals 1271b and 1272b and the upper bonding metals 1371b and 1372b may be formed of aluminum (Al), copper (Cu), tungsten (W), or the like.

The cell array structure CELL may provide at least one memory block. The cell array structure CELL may include a second substrate 1310 and a common source line 1320. A plurality of word lines 1330 (1331 to 1338) may be stacked on the second substrate 1310 along a direction parallel to the second substrate 1310 (direction D1). String select lines and a ground select line may be disposed on upper and lower portions of the word line 1330, respectively. The plurality of word lines 1330 may be disposed between the string select lines and the ground select line.

In the bit line bonding region BLBA, the channel structure CH may extend in a direction (third direction D3) perpendicular to the upper surface of the second substrate 1310 and penetrate the word lines 1330, the string select lines, and the ground select line. The channel structure CH may include a data storage layer, a channel layer, and a buried insulating layer. The channel layer may be electrically connected to a first metal layer 1350c and a second metal layer 1360c. For example, the first metal layer 1350c may be a bit line contact, and the second metal layer 1360c may be a bit line.

In the embodiment shown in FIG. 35, a region where the channel structure CH and the bit line 1360c are disposed may be defined as the bit line bonding region BLBA. The bit line 1360c may be electrically connected to the circuit elements 1220c providing a page buffer 1393 in the peripheral circuit structure PERI in the bit line bonding region BLBA. For example, the bit line 1360c may be connected to upper bonding metals 1371c and 1372c in the peripheral circuit structure PERI, and the upper bonding metals 1371c and 1372c may be connected to lower bonding metals 1271c and 1272c connected to circuit elements 1220c of the page buffer 1393. The lower bonding metals 1271c and 1272c and the upper bonding metals 1371c and 1372c may be formed of, for example, aluminum (Al), copper (Cu), tungsten (W), or the like.

In the word line bonding region WLBA, the word lines 1330 may extend along the first direction D1 parallel to the upper surface of the second substrate 1310, and may be connected to a plurality of cell contact plugs 1340 (1341 to 1347). The word lines 1330 and the cell contact plugs 1340 may be connected to each other through pads, provided by extending at least some of the word lines 1330 to different lengths. A first metal layer 1350b and a second metal layer 1360b may be sequentially connected to upper portions of the cell contact plugs 1340 connected to the word lines 1330. The cell contact plugs 1340 may be connected to the peripheral circuit structure PERI in the word line bonding region WLBA through the upper bonding metals 1371b and 1372b of the cell array structure CELL and the lower bonding metals 1271b and 1272b of the peripheral circuit structure PERI.

The cell contact plugs 1340 may be electrically connected to circuit elements 1220b forming a row decoder 1394 in the peripheral circuit structure PERI. In an embodiment of the present disclosure, the operating voltage of the circuit element 1220b forming the row decoder 1394 may be different from the operating voltage of the circuit element 1220c forming the page buffer 1393. For example, the operating voltage of the circuit element 1220c forming the page buffer 1393 may be higher than the operating voltage of the circuit element 1220b forming the row decoder 1394.

The circuit elements 1220c forming the page buffer 1393 may include the transistors described above with reference to FIGS. 1 to 16. For example, the source region SA and the drain region DA of the transistor may include a material having a bandgap higher than that of the semiconductor substrate 10, for example, may include silicon carbide (SiC) or gallium nitride (GaN).

A common source line contact plug 1380 may be positioned in the external pad bonding region PA. The common source line contact plug 1380 is formed of a conductive material such as metal, metal compound, or polysilicon (p-Si), and may be electrically connected to the common source line 1320. A first metal layer 1350a and a second metal layer 1360a may be sequentially stacked on the common source line contact plug 1380. For example, a region where the common source line contact plug 1380, the first metal layer 1350a, and the second metal layer 1360a are disposed may be defined as an external pad bonding region PA.

Input/output pads 1205 and 1305 may be disposed in the external pad bonding region PA. Referring to FIG. 35, a lower insulating layer 1201 covering a lower surface of the semiconductor substrate 10 may be positioned at the lower portion of the semiconductor substrate 10, and the first input/output pad 1205 may be formed on the lower insulating layer 1201. The first input/output pad 1205 is connected to at least one of the plurality of circuit elements 1220a, 1220b, or 1220c disposed on the peripheral circuit structure PERI through a first input/output contact plug 1203, and may be separated from the semiconductor substrate 10 by the lower insulating layer 1201. In addition, a side insulating layer may be disposed between the first input/output contact plug 1203 and the semiconductor substrate 10 to electrically separate the first input/output contact plug 1203 from the semiconductor substrate 10.

Referring to FIG. 35, an upper insulating layer 1301 covering the upper surface of the second substrate 1310 may be positioned on the upper portion of the second substrate 1310, and the second input/output pad 1305 may be positioned on the upper insulating layer 1301. The second input/output pad 1305 may be connected to at least one of the plurality of circuit elements 1220a, 1220b, or 1220c disposed in the peripheral circuit structure PERI through the second input/output contact plug 1303. In an embodiment of the present disclosure, the second input/output pad 1305 may be electrically connected to the circuit element 1220a.

Depending on embodiments, the second substrate 1310 and the common source line 1320 may not be positioned in the region where the second input/output contact plug 1303 is disposed. In addition, the second input/output pad 1305 may not overlap the word line 1380 in the third direction (direction D3). Referring to FIG. 35, the second input/output contact plug 1303 is separated from the second substrate 1310 and the common source line 1320 in a direction (e.g., first direction D1) parallel to the upper surface of the second substrate 1310, and may be connected to the second input/output pad 1305 penetrating the interlayer insulating layer 1315 of the cell array structure CELL.

Depending on embodiments, the first input/output pad 1205 and the second input/output pad 1305 may be selectively formed. For example, the semiconductor device 1100 may only include the first input/output pad 1205 disposed on the upper portion (in FIG. 35, lower portion) of the semiconductor substrate 10, or may only include the second input/output pad 1305 disposed on the upper portion of the second substrate 1310. Alternatively, the semiconductor device 1100 may include both the first input/output pad 1205 and the second input/output pad 1305.

The external pad bonding region PA and bit line bonding region BLBA included in each of the cell array structure CELL and peripheral circuit structure PERI may each have a metal pattern of the top metal layer as a dummy pattern, or the top metal layer may be blank.

In the external pad bonding region PA, the semiconductor device 1100 may form lower metal patterns 1272a and 1273a in a shape the same as that of an upper metal pattern 1372a of the cell array structure CELL on the top metal layer of the peripheral circuit structure PERI, corresponding to the upper metal pattern 1372a formed on the top metal layer of the cell array structure CELL. Similarly, the semiconductor device 1100 may form a lower metal patterns 1271a in a shape the same as that of an upper metal pattern 1371a of the cell array structure CELL on the top metal layer of the peripheral circuit structure PERI, corresponding to the upper metal pattern 1371a formed on the top metal layer of the cell array structure CELL. The lower metal pattern 1273a formed on the top metal layer of the peripheral circuit structure PERI may not be connected to a separate contact in the peripheral circuit structure PERI. Similarly, the top metal pattern 1372a having a shape the same as that of the lower metal pattern 1273a of the peripheral circuit structure PERI may be formed on the top metal layer of the cell array structure CELL, corresponding to the lower metal pattern 1273a formed on the top metal layer of the peripheral circuit structure PERI in the external pad bonding region PA. The lower metal patterns 1271a, 1272a, and 1273a and the upper metal patterns 1371a and 1372a may be formed of, for example, aluminum (Al), copper (Cu), tungsten (W), or the like.

Lower bonding metals 1271b and 1272b may be positioned on the second metal layer 1240b of the word line bonding region WLBA. In the word line bonding region WLBA, the lower bonding metals 1271b and 1272b of the peripheral circuit structure PERI may be electrically connected to the upper bonding metals 1371b and 1372b of the cell array structure CELL by a bonding method.

In addition, an upper metal pattern 1392 having a shape the same as that of a lower metal pattern 1252 of the peripheral circuit structure PERI may be formed on the top metal layer of the cell array structure CELL, corresponding to the lower metal pattern 1252 formed on the top metal layer of the peripheral circuit structure PERI in the bit line bonding region BLBA. A contact may not be formed on the upper metal pattern 1392 formed on the top metal layer of the cell array structure CELL.

Next, an electronic system including a semiconductor device according to an embodiment of the present disclosure will be described with reference to FIG. 36.

FIG. 36 is a diagram schematically illustrating an electronic system including a semiconductor device according to an embodiment of the present disclosure.

As shown in FIG. 36, an electronic system 1000 according to an embodiment of the present disclosure may include the semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 including one or a plurality of semiconductor devices 1100 may be, for example, a solid state drive device (SSD), a universal serial bus (USB), a computing system, a medical device, or a communication device.

The semiconductor device 1100 may be a non-volatile memory device, for example, a NAND flash memory device. The semiconductor device 1100 may include a first structure 1100F and a second structure 1100S on the first structure 1100F. In an embodiment of the present disclosure, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first gate upper line UL1, a second gate lower line UL2, and a first gate lower line LL1, a second gate lower line LL2, and a memory cell string CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to embodiments.

In an embodiment of the present disclosure, the lower transistors LT1 and LT2 may include ground selection transistors, and the first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wire 1115 extending from the first structure 1100F to the second structure 1100S. The bit line BL may be electrically connected to the page buffer 1120 through a second connection wire 1125 extending from the first structure 1100F to the second structure 1100S.

In the first structure 1100F, the decoder circuit 1110 and the page buffer 1120 may execute a control operation on at least one memory cell transistor selected from among the plurality of memory cell transistors MCT. The decoder circuit 1110 and the page buffer 1120 may be controlled by the logic circuit 1130. Each of the decoder circuit 1110, the page buffer 1120 and the logic circuit 1130 may include a plurality of circuit devices. Each of the circuit device may include the transistors described above with reference to FIGS. 1 to 16. For example, the source region SA and the drain region DA of the transistor may include a material having a bandgap higher than that of the semiconductor substrate 10, for example, may include silicon carbide (SiC) or gallium nitride (GaN). The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending from the first structure 1100F to the second structure 1100S.

The controller 1200 may include a processor 1210, a NAND controller 1220, and a host interface (HOST I/F) 1230. Depending on embodiments, the electronic system 1000 may include a plurality of semiconductor devices 1100. In this case, the controller 1200 may control the plurality of semiconductor devices 1100.

The processor 1210 may control the overall operation of the electronic system 1000 including the controller 1200. The processor 1210 may operate according to predetermined firmware, and may access the semiconductor device 1100 by controlling the NAND controller 1220. The NAND controller 1220 may include a NAND interface (NAND I/F) 1221 processing communication with the semiconductor device 1100. Through the NAND interface 1221, a control instruction for controlling the semiconductor device 1100, data to be written to the memory cell transistor MCT of the semiconductor device 1100, and data to be read from the memory cell transistor MCT of the semiconductor device 1100 may be transmitted. The host interface 1230 may provide a communication function between the electronic system 1000 and an external host. When a control instruction is received from an external host through the host interface 1230, the processor 1210 may control the semiconductor device 1100 in response to the control instruction.

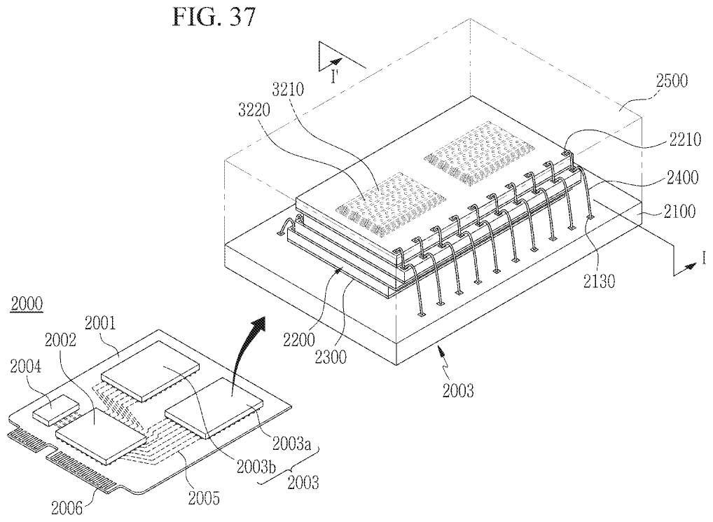

FIG. 37 is a perspective view schematically illustrating an electronic system including a semiconductor device according to an embodiment of the present disclosure.

As shown in FIG. 37, an electronic system 2000 according to an embodiment of the present disclosure may include a main substrate 2001, a controller 2002 mounted on the main substrate 2001, one or more semiconductor packages 2003, and a dynamic random access memory (DRAM) 2004. The semiconductor package 2003 and the DRAM 2004 may be connected to the controller 2002 through a wire pattern 2005 formed on the main substrate 2001.

The main board 2001 may include a connector 2006 including a plurality of pins coupled to an external host. The number and arrangement of the plurality of pins in the connector 2006 may vary depending on the communication interface between the electronic system 2000 and the external host. In an embodiment of the present disclosure, the electronic system 2000 may communicate with the external host according to any one of interfaces such as, for example, universal serial bus (USB), peripheral component interconnect express (PCI-Express), serial advanced technology attachment (SATA), M-Phy for universal flash storage (UFS), and the like. In an embodiment of the present disclosure, the electronic system 2000 may operate with power supplied from an external host through the connector 2006. The electronic system 2000 may further include a power management integrated circuit (PMIC) that distributes the power supplied from the external host to the controller 2002 and the semiconductor package 2003.

The controller 2002 may write data to the semiconductor package 2003 or read data from the semiconductor package 2003, and may increase the operating speed of the electronic system 2000.

The DRAM 2004 may be a buffer memory for mitigating a speed difference between the semiconductor package 2003, which is a data storage space, and an external host. The DRAM 2004 included in the electronic system 2000 may also operate as a kind of cache memory, and may provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller 1220 for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a plurality of semiconductor chips 2200 disposed on the package substrate 2100, an adhesive layer 2300 disposed on a lower surface of each of the semiconductor chips 2200, connection structures 2400 electrically connecting the semiconductor chips 2200 to the package substrate 2100, and a molding layer 2500 covering the semiconductor chips 2200 and the connection structure 2400 on the package substrate 2100.

The package substrate 2100 may be a printed circuit board (PCB) including packages upper pads 2130. Each semiconductor chip 2200 may include an input/output pad 2210. The input/output pad 2210 may correspond to the input/output pad 1101 of FIG. 36. Each semiconductor chip 2200 may include a gate stacking structure 3210 and a channel structure 3220. The semiconductor chip 2200 may include the semiconductor device described above. For example, the semiconductor chip 2200 may include the transistors described above with reference to FIGS. 1 to 16. For example, the source region SA and the drain region DA of the transistor may include a material having a bandgap higher than that of the semiconductor substrate 10, for example, may include silicon carbide (SiC) or gallium nitride (GaN).

In an embodiment of the present disclosure, the connection structure 2400 may be a bonding wire electrically connecting the input/output pad 2210 to the package upper pad 2130. Accordingly, in each of the first and second semiconductor packages 2003a and 2003b, the semiconductor chips 2200 may be electrically connected to each other using a bonding wire method, and may be electrically connected to the package upper pad 2130 of the package substrate 2100. According to an embodiment of the present disclosure, in each of the first and second semiconductor packages 2003a and 2003b, the semiconductor chips 2200 may be electrically connected to each other by a connection structure including a through silicon via (TSV) instead of the connection structure 2400 of the bonding wire type.

In an embodiment of the present disclosure, the controller 2002 and the semiconductor chip 2200 may be included in one package. In an embodiment of the present disclosure, the controller 2002 and the semiconductor chip 2200 may be mounted on a separate interposer substrate different from the main substrate 2001, and the controller 2002 and the semiconductor chip 2200 may be connected to each other by a wire formed on the interposer substrate.

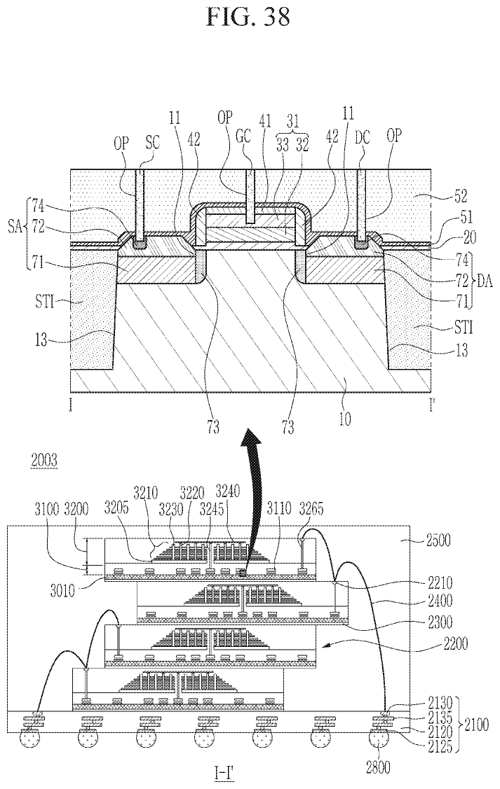

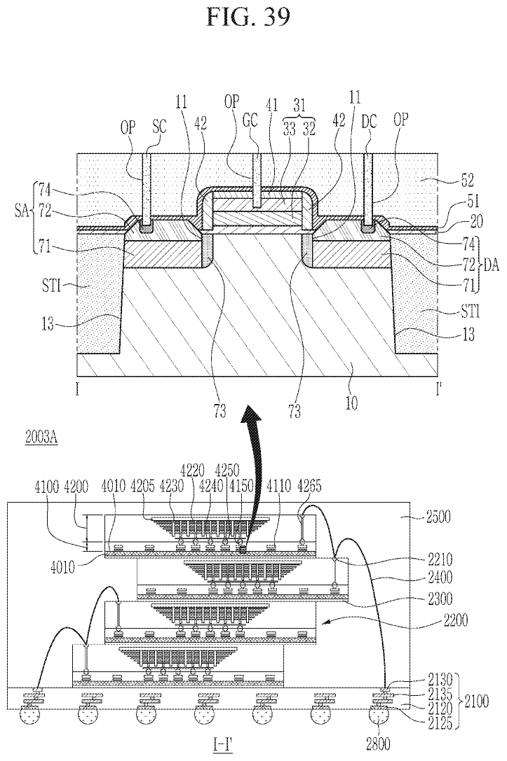

FIGS. 38 and 39 are cross-sectional views, schematically illustrating a semiconductor package according to an embodiment of the present disclosure, respectively. FIGS. 38 and 39 each describe an embodiment of the present disclosure for the semiconductor package 2003 of FIG. 37, and conceptually show a region obtained by cutting the semiconductor package 2003 of FIG. 37 along the cutting line I-I′.

Referring to FIG. 38, in the semiconductor package 2003, the package substrate 2100 may be a printed circuit board (PCB). The package substrate 2100 may include a package substrate body 2120, a package upper pad 2130 disposed on the upper surface of the package substrate body 2120, a lower pad 2125 disposed on a lower surface of the package substrate body 2120 or exposed through the lower surface of the package substrate body 2120, and an internal wire 2135 electrically connecting the upper pad 2130 to the lower pad 2125 inside the package substrate body 2120. The upper pad 2130 may be electrically connected to the connection structure 2400. The lower pad 2125 may be connected to the wire pattern 2005 of the main substrate 2001 of the electronic system 2000 through a conductive connector 2800, as shown in FIG. 38.

The semiconductor chip 2200 may include a semiconductor substrate 3010, and a first structure 3100 and a second structure 3200 sequentially stacked on the semiconductor substrate 3010, respectively. The first structure 3100 may include a peripheral circuit region including a peripheral wire 3110. For example, the first structure 3100 may include a plurality of transistors as described above with reference to FIGS. 1 to 16. For example, the source region SA and the drain region DA of the transistor may include a material having a bandgap higher than that of the semiconductor substrate 10, for example, may include silicon carbide (SiC) or gallium nitride (GaN). The second structure 3200 may include a common source line 3205, a gate stacking structure 3210 on the common source line 3205, a channel structure 3220 and an isolation structure 3230 penetrating the gate stacking structure 3210, a bit line 3240 electrically connected to the channel structure 3220, and a gate connection wire electrically connected to the word line of the gate stacking structure 3210.

In the semiconductor chip 2200 or the semiconductor device 1100 according to an embodiment of the present disclosure may include the transistors described above with reference to FIGS. 1 to 16. For example, the source region SA and the drain region DA may include a material having a bandgap higher than that of the semiconductor substrate 10, and the source region SA and the drain region DA may respectively include the first lightly doped region 71 and the second lightly doped region 72 overlapping in a direction perpendicular to the upper surface of the semiconductor substrate 10. The first lightly doped region 71 and the second lightly doped region 72 may form a PN junction. As described above, since the source region SA and the drain region DA include a material having a bandgap higher than that of the semiconductor substrate 10, the breakdown voltage increases and high-voltage driving is enabled.

Each semiconductor chip 2200 may include a penetration wire 3245 electrically connected to the peripheral wire 3110 of the first structure 3100 and extending into the second structure 3200. The penetration wire 3245 may penetrate the gate stacking structure 3210, and may be further disposed outside the gate stacking structure 3210. Each semiconductor chip 2200 may further include an input/output connection wire 3265 electrically connected to the peripheral wire 3110 of the first structure 3100 and extending into the second structure 3200, and the input/output pad 2210 electrically connected to the input/output connection wire 3265.

In an embodiment of the present disclosure, the plurality of semiconductor chips 2200 in the semiconductor package 2003 may be electrically connected to each other by a connection structure 2400 in the shape of a bonding wire. As another example, the plurality of semiconductor chips 2200 or the plurality of portions included in the plurality of semiconductor chips 2200 may be electrically connected by a connection structure including a through silicon via (TSV).

Referring to FIG. 39, in a semiconductor package 2003A, each semiconductor chip 2200 may include a semiconductor substrate 4010, a first structure 4100 on the semiconductor substrate 4010, and a second structure 4200 bonded to the first structure 4100 by a wafer bonding method on the first structure 4100.

The first structure 4100 may include a peripheral circuit region including a peripheral wire 4110 and a first junction structure 4150. For example, the first structure 4100 may include a plurality of transistors as described above with reference to FIGS. 1 to 16. For example, the source region SA and the drain region DA of the transistor may include a material having a bandgap higher than that of the semiconductor substrate 10, for example, may include silicon carbide (SiC) or gallium nitride (GaN). The second structure 4200 may include a common source line 4205, a gate stacking structure 4210 between the common source line 4205 and the first structure 4100, a channel structure 4220 and an isolation structure 4230 penetrating the gate stacking structure 4210, and a second junction structure 4250 electrically connected to the word lines of the channel structure 4220 and the gate stacking structure 4210, respectively. For example, the second junction structure 4250 may be electrically connected to the channel structure 4220 and the word line WL, respectively. For example, the second junction structure 4250 may be electrically connected to the channel structure 4220 through a bit line 4240, and may be electrically connected to the word line WL through a gate connection wire. The first junction structure 4150 of the first structure 4100 and the second junction structure 4250 of the second structure 4200 may be bonded to each other while contacting each other. A bonded portion of the first junction structure 4150 and the second junction structure 4250 may be formed of, for example, copper (Cu).

In the semiconductor chip 2200 or the semiconductor device according to an embodiment of the present disclosure may include the transistors described above with reference to FIGS. 1 to 16. For example, the source region SA and the drain region DA may include a material having a bandgap higher than that of the semiconductor substrate 10, and the source region SA and the drain region DA may respectively include the first lightly doped region 71 and the second lightly doped region 72 overlapping in a direction perpendicular to the upper surface of the semiconductor substrate 10. The first lightly doped region 71 and the second lightly doped region 72 may form a PN junction. As described above, since the source region SA and the drain region DA include a material having a bandgap higher than that of the semiconductor substrate 10, the breakdown voltage increases at the same resistance, and high-voltage driving is enabled.

Each semiconductor chip 2200 may further include an input/output connection wire 4265 disposed on the lower portion of the input/output pad 2210 and electrically connected to the input/output pad 2210. The input/output connection wire 4265 may be electrically connected to a part of the second junction structure 4250.

In an embodiment of the present disclosure, the plurality of semiconductor chips 2200 in the semiconductor package 2003 may be electrically connected to each other by the connection structure 2400 in the shape of a bonding wire. As another example, the plurality of semiconductor chips 2200 or the plurality of parts included in the plurality of semiconductor chips 2200 may be electrically connected by a connection structure including a through silicon via (TSV).

While the embodiments of the present disclosure have been described in detail, it is to be understood that the disclosure is not limited to the disclosed embodiments, but on the contrary, is intended to cover various modifications and equivalent arrangements made therein without departing from the spirit and scope of the present disclosure as defined by the appended claims.

What is claimed is:

1. A semiconductor device, comprising:
a semiconductor substrate including a plurality of trenches and silicon;
a gate electrode positioned on the semiconductor substrate and between the trenches; and
a source region and a drain region respectively positioned within the trenches,
wherein the source region and the drain region include SiC or GaN,
the source region and the drain region each includes a first lightly doped region and a second lightly doped region,
a whole of the first lightly doped region overlaps the second lightly doped region in a direction perpendicular to an upper surface of the semiconductor substrate.

2. The semiconductor device of claim 1, wherein
the SiC includes at least one of 4H-SIC, 6H-SIC, or 3C-SiC.

3. The semiconductor device of claim 1, wherein
the first lightly doped region includes P-type impurity,
the second lightly doped region includes N-type impurity,
the first lightly doped region and the second lightly doped region form a PN junction, and
the second lightly doped region is positioned closer to the gate electrode than the first lightly doped region.

4. The semiconductor device of claim 1, wherein
doping concentration of each of the first lightly doped region and the second lightly doped region is in a range from about 10¹⁵ cm⁻³ to about 10¹⁷ cm⁻³.

5. The semiconductor device of claim 1, wherein
the semiconductor substrate further comprises a second impurity doped region positioned between the source region and the gate electrode, and between the drain region and the gate electrode.

6. The semiconductor device of claim 5, wherein
the second impurity doped region includes N-type impurity,
doping concentration of the second impurity doped region is in a range from about 10¹⁵ cm⁻³ to about 10¹⁷ cm⁻³.

7. The semiconductor device of claim 1, further comprising:
a second heavily doped region positioned within the second lightly doped region,
wherein the second heavily doped region has a doping concentration higher than that of the second lightly doped region.

8. The semiconductor device of claim 7, further comprising:
an interlayer insulating layer positioned above the source region, the gate electrode and the drain region; and
a source contact and a drain contact positioned above the interlayer insulating layer,
wherein the interlayer insulating layer includes a first opening overlapping the source region and a second opening overlapping the drain region,
the second heavily doped region of the source region is in direct contact with the source contact at the first opening,
the second heavily doped region of the drain region and the drain contact are in direct contact at the second opening.

9. The semiconductor device of claim 1, further comprising:
an isolation layer positioned within the semiconductor substrate and defining a plurality of active regions; and
an isolation impurity region positioned below the isolation layer,
wherein the isolation impurity region includes P-type impurity.

10. The semiconductor device of claim 1, wherein
a depth of each of the trenches is in a range from about 100 nm to about 1000 nm.

11. The semiconductor device of claim 1, wherein
an upper surface of each of the source region and the drain region has a shape in which an area on a plane becomes narrower toward the top.

12. The semiconductor device of claim 1, wherein
an area on a plane for each of the source region and the drain region at an upper surface and an area on a plane for each of the source region and the drain region at a lower surface have a same size.

13. The semiconductor device of claim 1, wherein
top surfaces of the source region and the drain region protrude from the upper surface of the semiconductor substrate.

14. The semiconductor device of claim 1, wherein
in the source region and the drain region, a thickness of the first lightly doped region is thicker than a thickness of the second lightly doped region.

15. A semiconductor device, comprising:
a peripheral circuit structure; and
a cell array structure disposed on the peripheral circuit structure,
wherein the cell array structure includes memory cells arranged three-dimensionally on a semiconductor layer,
the peripheral circuit structure comprises:
a semiconductor substrate including a plurality of trenches and silicon;
a gate electrode positioned on the semiconductor substrate and between the trenches; and
a source region and a drain region respectively positioned within the trenches,
wherein the source region and the drain region include SiC or GaN,
the source region and the drain region each includes a first lightly doped region and a second lightly doped region,
a whole of the first lightly doped region overlaps the second lightly doped region in a direction perpendicular to an upper surface of the semiconductor substrate.

16. The semiconductor device of claim 15, wherein
the first lightly doped region includes P-type impurity,
the second lightly doped region includes N-type impurity,
the first lightly doped region and the second lightly doped region form a PN junction,
the second lightly doped region is positioned closer to the gate electrode than the first lightly doped region is, and
doping concentration of each of the first lightly doped region and the second lightly doped region is in a range from about 10¹⁵ cm⁻³ to about 10¹⁷ cm⁻³.

17. The semiconductor device of claim 15, wherein
the semiconductor substrate further comprises a second impurity doped region positioned between the source region and the gate electrode, and between the drain region and the gate electrode.

18. The semiconductor device of claim 15, wherein
top surfaces of the source region and the drain region protrude from the upper surface of the semiconductor substrate.

19. An electronic system, comprising:
a main substrate;
a semiconductor device disposed on the main substrate; and
a controller electrically connected to the semiconductor device on the main substrate,
wherein the semiconductor device includes a peripheral circuit structure and a cell array structure positioned above the peripheral circuit structure,
the cell array structure includes memory cells arranged three-dimensionally on a semiconductor layer, and
the peripheral circuit structure comprises:
a semiconductor substrate including a plurality of trenches and silicon;
a gate electrode positioned on the semiconductor substrate and between the trenches; and
a source region and a drain region respectively positioned within the trenches,
wherein the source region and the drain region include SiC or GaN,
the source region and the drain region each includes a first lightly doped region and a second lightly doped region,
a whole of the first lightly doped region overlaps the second lightly doped region in a direction perpendicular to an upper surface of the semiconductor substrate.

20. The electronic system of claim 19, wherein
the first lightly doped region includes P-type impurity,
the second lightly doped region includes N-type impurity,
the first lightly doped region and the second lightly doped region form a PN junction,
the second lightly doped region is positioned closer to the gate electrode than the first lightly doped region is, and
doping concentration of each of the first lightly doped region and the second lightly doped region is in a range from about 10¹⁵ cm⁻³ to about 10¹⁷ cm⁻³.
